(19) United States
(12) Patent Application Publication
(10) Pub. No.: US 2024/0324168 A1
(43) Pub. Date: Sep. 26, 2024

(54) METHOD OF MANUFACTURING SEMICONDUCTOR DEVICES

(71) Applicant: Samsung Electronics Co., Ltd., Suwon-si (KR)

(72) Inventors: Soyoung LEE, Suwon-si (KR); Janghee LEE, Suwon-si (KR)

(73) Assignee: Samsung Electronics Co., Ltd., Suwon-si (KR)

(21) Appl. No.: 18/609,430

(22) Filed: Mar. 19, 2024

(30) Foreign Application Priority Data
Mar. 24, 2023 (KR) 10-2023-0039134
Apr. 12, 2023 (KR) 10-2023-0048319

(51) Int. Cl. H10B 12/00

(52) U.S. Cl. CPC H10B 12/02; H10B 12/315; H10B 12/482; H10B 12/488

(57) ABSTRACT

A method of manufacturing a semiconductor device includes forming a target layer on a substrate, forming a mask pattern on the substrate including the target layer, and etching the target layer using the mask pattern as an etching mask to form a resulting pattern, wherein the mask pattern includes a first mask layer including an amorphous metal oxide, an amorphous insulating material including an amorphous metal oxide or no metal, and an upper mask layer and a lower mask layer covering upper and lower surfaces of the first mask layer, respectively.

### CROSS-REFERENCE TO RELATED APPLICATION

This application is based on and claims priority under 35 U.S.C. § 119 to Korean Patent Application Nos. 10-2023-0039134, filed on Mar. 24, 2023, and 10-2023-0048319, filed on Apr. 12, 2023, in the Korean Intellectual Property Office, the disclosure of which is incorporated by reference herein in its entirety.

### BACKGROUND

The inventive concepts relate to methods of manufacturing a semiconductor device, and more specifically, to methods of manufacturing a semiconductor device using a mask pattern.

According to the rapid development of the electronics industry and the needs of users, electronic devices are becoming smaller and lighter. Therefore, a high degree of integration is also required for semiconductor devices used in electronic devices. As the degree of integration of semiconductor devices increases, reduction of design rules and increase in the aspect ratio for configurations of semiconductor devices are required, and the process difficulty for forming configurations of semiconductor devices is increasing.

### SUMMARY

Some example embodiments of the inventive concepts provide methods of manufacturing a semiconductor device having a high degree of integration.

According to an aspect of the inventive concepts, a manufacturing method of a semiconductor device may include preparing a substrate including a plurality of active regions defined by an element isolation film, forming a word line trench extending in a first horizontal direction across the plurality of active regions in the substrate by removing a portion of the element isolation film and a portion of each of the plurality of active regions using a first mask pattern, forming a word line within the word line trench, forming a second mask pattern defining a direct contact hole extending into the substrate on the substrate where the word line is formed, forming a direct contact conductive layer including metal or a metal compound as a conductive material to fill the direct contact hole, forming a plurality of bit line structures, each including a bit line, the plurality of bit line structures being parallel to each other in the first horizontal direction and extending in a second horizontal direction orthogonal to the first horizontal direction on the second mask pattern and the direct contact conductive layer, forming a plurality of direct contact conductive patterns by etching the direct contact conductive layer using the plurality of bit line structures and the second mask pattern as etching masks, forming a plurality of buried contacts and a plurality of landing pads on the plurality of buried contacts, the plurality of buried contacts electrically connected to the plurality of active regions, and the plurality of landing pads filling a portion of a space between the plurality of bit line structures, forming a mold layer on the plurality of bit line structures and the plurality of landing pads, forming a plurality of mold openings by etching the mold layer using a third mask pattern, and forming a plurality of lower electrodes filling the plurality of mold openings, wherein at least one of the first mask pattern, the second mask pattern, and the third mask pattern has a stacked structure of a first mask layer and at least two second mask layers, the first mask layer including an amorphous metal oxide, and the at least two second mask layers including an amorphous metal oxide or an amorphous insulating material that does not include metal.

According to another aspect of the inventive concepts, a manufacturing method of a semiconductor device may include forming a target layer on a substrate, forming a mask pattern on the substrate including the target layer, and forming a resulting pattern by etching the target layer using the mask pattern, wherein the mask pattern includes a first mask layer containing an amorphous metal oxide, and an upper mask layer and a lower mask layer including an amorphous metal oxide or an amorphous insulating material that does not include metal, the an upper mask layer and the lower mask layer covering upper and lower surfaces of the first mask layer, respectively.

According to another aspect of the inventive concepts, a manufacturing method of a semiconductor device may include forming a base layer covering a substrate, forming a mask pattern on the base layer, patterning the base layer to define a first contact hole therein using the mask pattern, forming a target layer made of metal or a metal compound that is a conductive material while filling the first contact hole, forming a mask pattern structure on the mask pattern and the target layer, and forming a resulting pattern and a second contact hole by etching the target layer using the mask pattern and the mask pattern structure as an etch mask, wherein the mask pattern includes a first mask layer containing an amorphous metal oxide, and an upper mask layer and a lower mask layer including an amorphous metal oxide or an amorphous insulating material that does not include metal, the upper mask layer and the lower mask layer covering upper and lower surfaces of the first mask layer, respectively.

### BRIEF DESCRIPTION OF THE DRAWINGS

Example embodiments will be more clearly understood from the following detailed description taken in conjunction with the accompanying drawings in which:

FIG. 1 is a block diagram illustrating a semiconductor device according to an example embodiment;

FIG. 2 is a schematic plan layout for explaining main components of a semiconductor device according to an example embodiment of the present inventive concepts;

FIGS. 3A to 16D are cross-sectional views illustrating a method of manufacturing a semiconductor device, according to an example embodiment, and FIGS. 17A to 17D are cross-sectional views illustrating a semiconductor device according to an example embodiment;

FIGS. 18A and 18B are enlarged cross-sectional views illustrating a mask pattern used in a method of manufacturing a semiconductor device, according to some example embodiments;

FIGS. 19A and 19B are enlarged cross-sectional views illustrating a semiconductor device according to some example embodiments;

FIGS. 20A and 20B are enlarged cross-sectional views illustrating a mask pattern used in a method of manufacturing a semiconductor device, according to some example embodiments;

FIGS. 21A to 21C are cross-sectional views illustrating a method of manufacturing a semiconductor device, using a mask pattern according to an example embodiment;

FIGS. 22A to 22C are cross-sectional views illustrating a method of manufacturing a semiconductor device, using a mask pattern according to an example embodiment; and

FIGS. 23A to 23E are cross-sectional views illustrating a method of manufacturing a semiconductor device, using a mask pattern according to an example embodiment.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

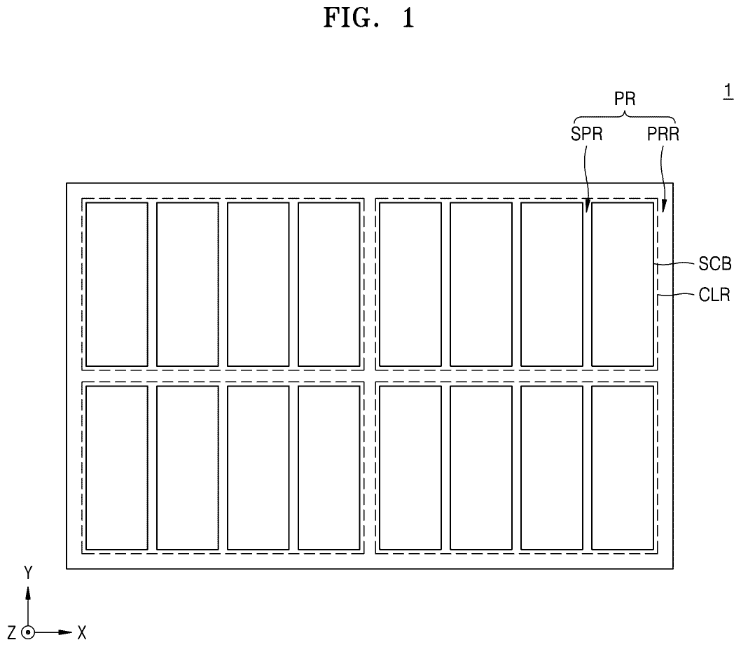

FIG. 1 is a plan view illustrating a semiconductor device according to an example embodiment.

Referring to FIG. 1, a semiconductor device 1 may include a cell region CLR in which memory cells are disposed and a main peripheral region PRR surrounding the cell region CLR.

According to an example embodiment, sub peripheral regions SPR dividing cell blocks SCB may be included in the cell region CLR. A plurality of memory cells may be disposed in the cell blocks SCB.

Logic cells for input/output of electrical signals to/from the memory cells may be disposed in the main peripheral region PRR and the sub peripheral region SPR. In some example embodiments, the main peripheral region PRR may be referred to as a peripheral circuit region and the sub peripheral region SPR may be referred to as a core circuit region. A peripheral region PR may include a main peripheral region PRR and sub peripheral regions SPR. That is, the peripheral region PR may be a core and a peripheral circuit region including a peripheral circuit region and a core circuit region. In some example embodiments, at least a portion of the sub peripheral region SPR may be provided only as a space for dividing cell blocks SCB.

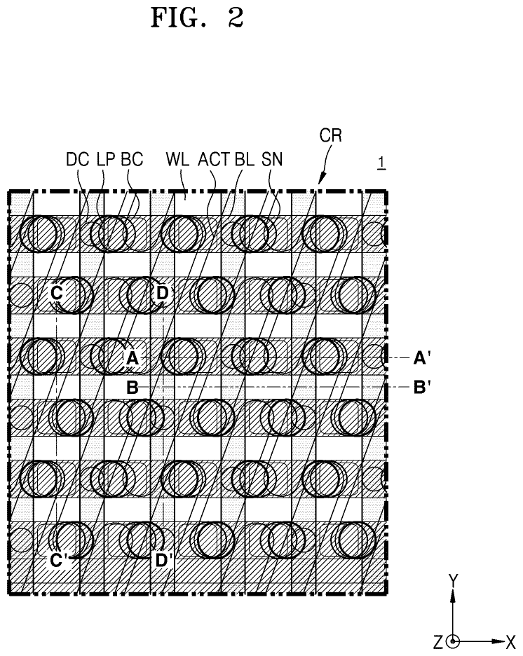

FIG. 2 is a schematic plan layout for explaining main components of a semiconductor device according to an example embodiment of the present inventive concepts.

Referring to FIG. 2, the semiconductor device 1 includes a memory cell region CR. The semiconductor device 1 may include a plurality of active regions ACT disposed in the memory cell region CR. The memory cell region CR may be a cell block SCB in which a plurality of memory cells shown in FIG. 1 are disposed. A plurality of active regions ACT disposed in the memory cell region CR are disposed to have long axes in an oblique direction with respect to the first horizontal direction (X direction) and the second horizontal direction (Y direction) and may each have a wavy planar shape. In some example embodiments, the plurality of active regions ACT may be arranged in rows in an oblique direction with respect to the first horizontal direction (X direction) and the second horizontal direction (Y direction) and may be arranged in rows in the second horizontal direction (Y direction).

The plurality of word lines WL may extend parallel to each other in the first horizontal direction (X direction) across the plurality of active regions ACT in the memory cell region CR. In some example embodiments, a pair of word lines WL may extend parallel to each other in the first horizontal direction (X direction) on one active region ACT. A plurality of bit lines BL may extend parallel to each other in the second horizontal direction (Y direction) crossing the first horizontal direction (X direction) on the plurality of word lines WL. In some example embodiments, one bit line BL may extend in the second horizontal direction (Y direction) on one active region ACT. A plurality of bit lines BL may be connected to a plurality of active regions ACT through a plurality of direct contacts DC. The plurality of direct contacts DB may be disposed at portions where the plurality of bit lines BL and the plurality of active regions ACT cross each other.

In some example embodiments, a plurality of buried contacts BC may be formed between two adjacent bit lines BL among the plurality of bit lines BL. In some example embodiments, the plurality of buried contacts BC may be arranged in a line in each of the first horizontal direction (X direction) and the second horizontal direction (Y direction). In some example embodiments, a pair of buried contacts BC may be connected to one active region ACT. For example, one buried contact BC may be connected to both ends of one active region ACT.

A plurality of landing pads LP may be formed on the plurality of buried contacts BC. The plurality of landing pads LP may be arranged to at least partially overlap the plurality of buried contacts BC. In some example embodiments, each of the plurality of landing pads LP may extend to an upper portion of any one bit line BL among two mutually adjacent bit lines BL.

A plurality of storage nodes SN may be formed on the plurality of landing pads LP. A plurality of storage nodes SN may be formed on top of a plurality of bit lines BL. Each of the plurality of storage nodes SN may be a lower electrode of a plurality of capacitors. The storage node SN may be connected to the active region ACT through the landing pad LP and the buried contact BC.

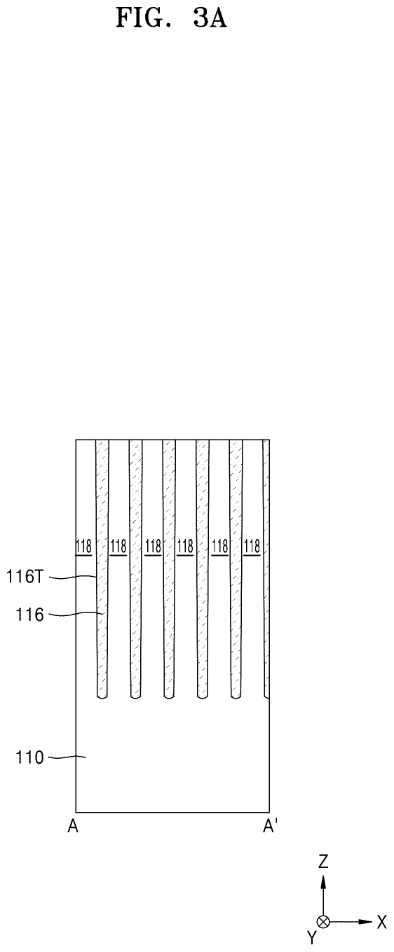

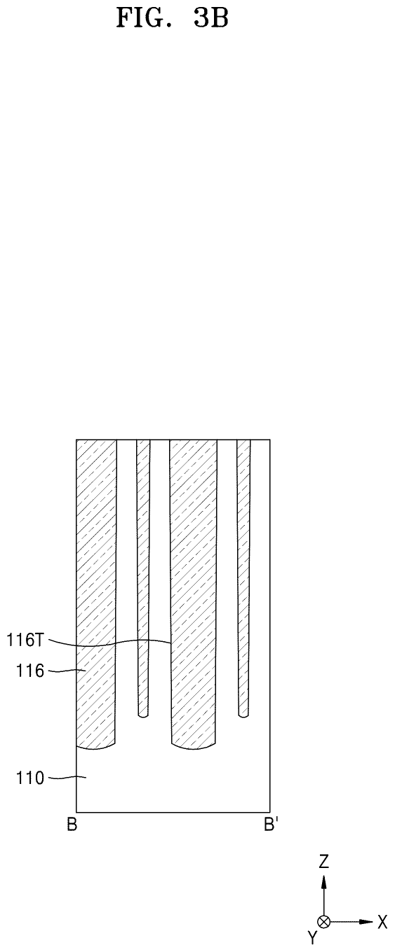

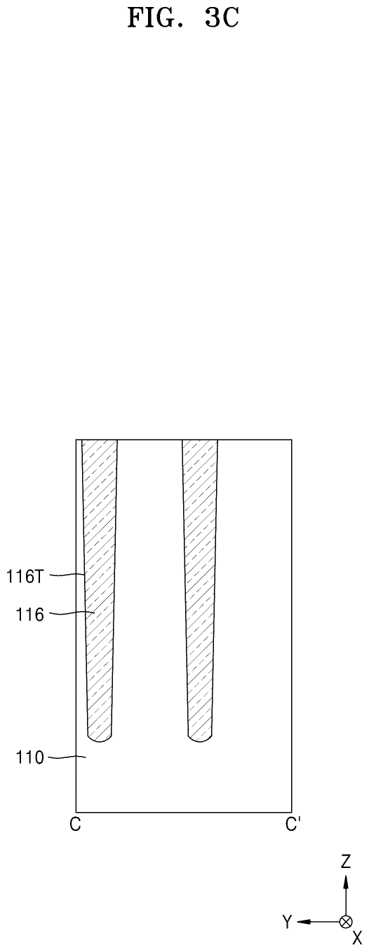

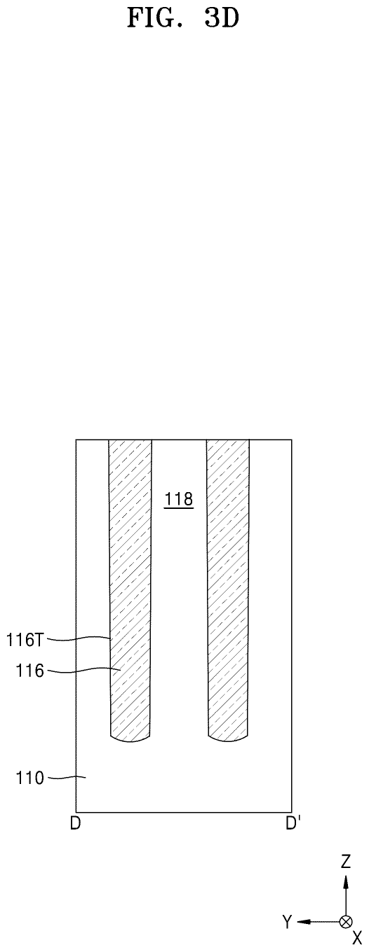

FIGS. 3A to 16D are cross-sectional views illustrating a method of manufacturing a semiconductor device, according to an example embodiment, and FIGS. 17A to 17D are cross-sectional views illustrating a semiconductor device according to an example embodiment. For example, FIGS. 3A, 4A, 5A, 6A, 7A, 8A, 9A, 10A, 11A, 12A, 13A, 14A, 15A, 16A, and 17A are cross-sectional views taken along the position corresponding to line A-A′ in FIG. 2, FIGS. 3B, 4B, 5B, 6B, 7B, 8B, 9B, 10B, 11B, 12B, 13B, 14B, 15B, 16B, and 17B are cross-sectional views taken along the position corresponding to the line B-B′ in FIG. 2, FIGS. 3C, 4C, 5C, 6C, 7C, 8C, 9C, 10C, 11C, 12C, 13C, 14C, 15C, 16C, and 17C are cross-sectional views taken along the position corresponding to line C-C′ in FIG. 2, and FIGS. 3D, 4D, 5D, 6D, 7D, 8D, 9D, 10D, 11D, 12D, 13D, 14D, 15D, 16D, and 17D are cross-sectional views taken along a position corresponding to line D-D′ in FIG. 2.

Referring to FIGS. 3A to 3D together, an element isolation trench 116T may be formed in the substrate 110 and an element isolation film 116 filling the element isolation trench 116T may be formed. In some example embodiments, the element isolation trench 116T and the plurality of active regions 118 defined by the element isolation trench 116T may be formed through an extreme ultraviolet (EUV) lithography process.

The substrate 110 may include, for example, silicon (Si), crystalline Si, polycrystalline Si, or amorphous Si. In some other example embodiments, the substrate 110 may include a semiconductor element, such as germanium (Ge), or at least one compound semiconductor selected from silicon germanium (SiGe), silicon carbide (SiC), gallium arsenide (GaAs), indium arsenide (InAs), and indium phosphide (InP). In some example embodiments, the substrate 110 may have a silicon on insulator (SOI) structure. For example, the substrate 110 may include a buried oxide (BOX) layer. The substrate 110 may include a conductive region, for example, a well doped with impurities or a structure doped with impurities. The element isolation film 116 may be made of a material including at least one of, for example, silicon oxide, silicon nitride, and silicon oxynitride. The element isolation film 116 may be composed of a single layer made of one kind of insulating film, a double layer made of two kinds of insulating film, or a multi-layer made of a combination of at least three kinds of insulating films. For example, the element isolation film 116 may be composed of a double layer or a multi-layer made of an oxide film and a nitride film. However, according to the inventive concepts, the configuration of the element isolation film 116 is not limited to the above.

A plurality of active regions 118 may be defined on the substrate 110 in the memory cell region CR by the element isolation film 116. Like the active region ACT illustrated in FIG. 2, the active region 118 may have a relatively long island shape that has a minor axis and a major axis in a plan view and extends in the direction of the major axis. The plurality of active regions 118 may be arranged in rows in an oblique direction with respect to the first horizontal direction (X direction) and the second horizontal direction (Y direction) and may be arranged in rows in the second horizontal direction (Y direction).

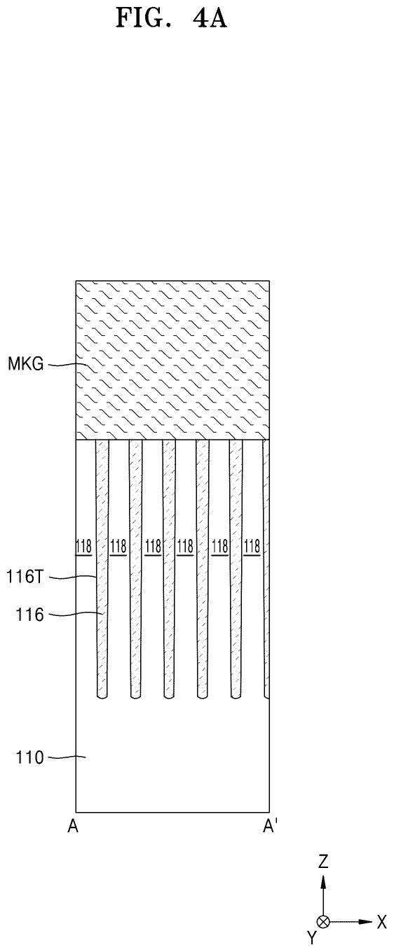

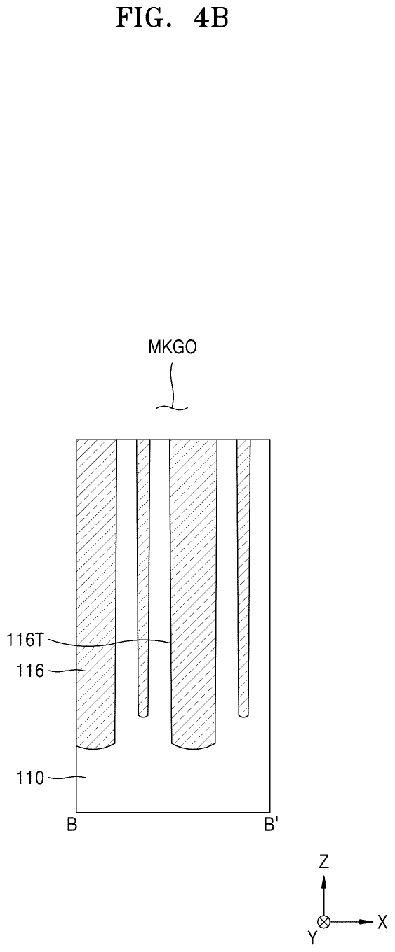

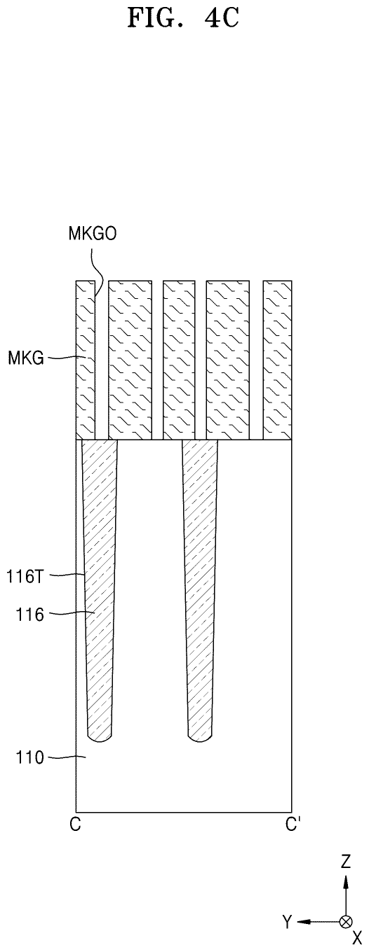

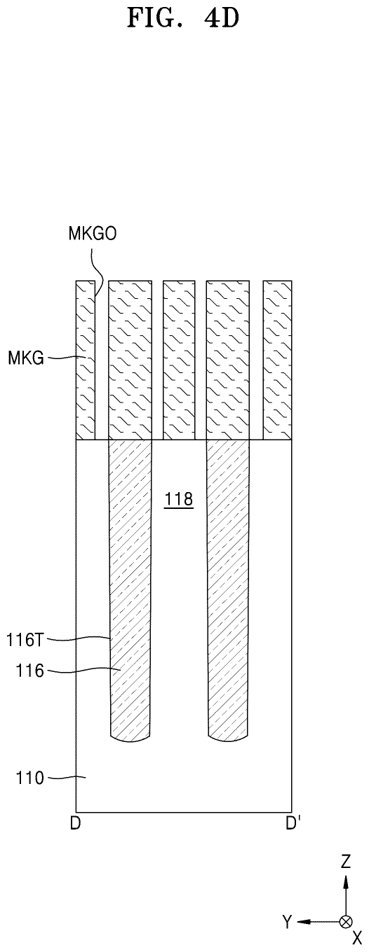

Referring to FIGS. 4A to 4D together, a plurality of first mask patterns MKG are formed on the substrate 110 on which the element isolation film 116 defining the active region 118 is formed. The plurality of first mask patterns MKG extends parallel to each other in the first horizontal direction (X direction), each may have a line shape, and are disposed to have substantially equal intervals in the second horizontal direction (Y direction) while crossing the active region 118. A first mask opening MKGO may be defined between two first mask patterns MKG that are adjacent to each other in the second horizontal direction (Y direction) among the plurality of first mask patterns MKG. A portion of the active region 118 and a portion of the element isolation film 116 may be exposed on the lower surface of the first mask opening MKGO.

The plurality of first mask patterns MKG may be amorphous. Each of the plurality of first mask patterns MKG may include metal oxide. Each of the plurality of first mask patterns MKG may have a stack structure including at least one first mask layer and two or more second mask layers. In some example embodiments, each of the plurality of first mask patterns MKG may have a stacked structure in which the first mask layer is disposed between two second mask layers. In some other example embodiments, the plurality of first mask patterns MKG include a plurality of first mask layers and a plurality of second mask layers, and first mask layers are respectively disposed between two of the second mask layers adjacent to each other in the vertical direction (Z direction) among the plurality of second mask layers, so that the plurality of first mask patterns MKG may have a stacked structure in which a plurality of first mask layers and a plurality of second mask layers are alternately stacked in the vertical direction (Z direction).

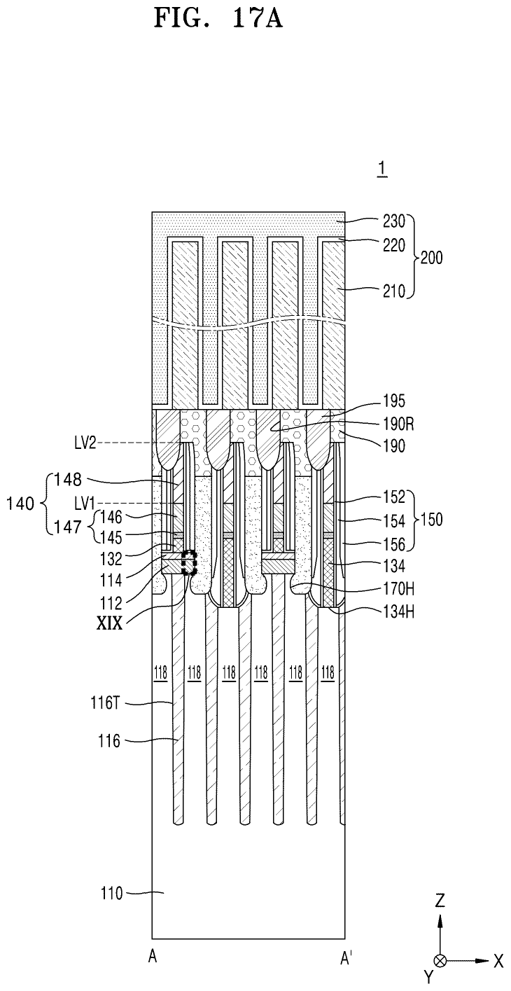

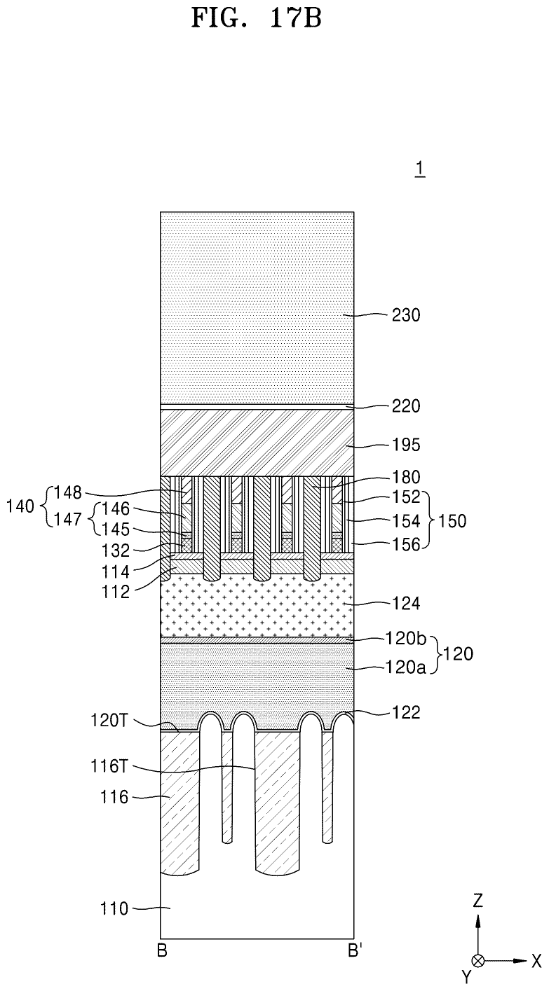

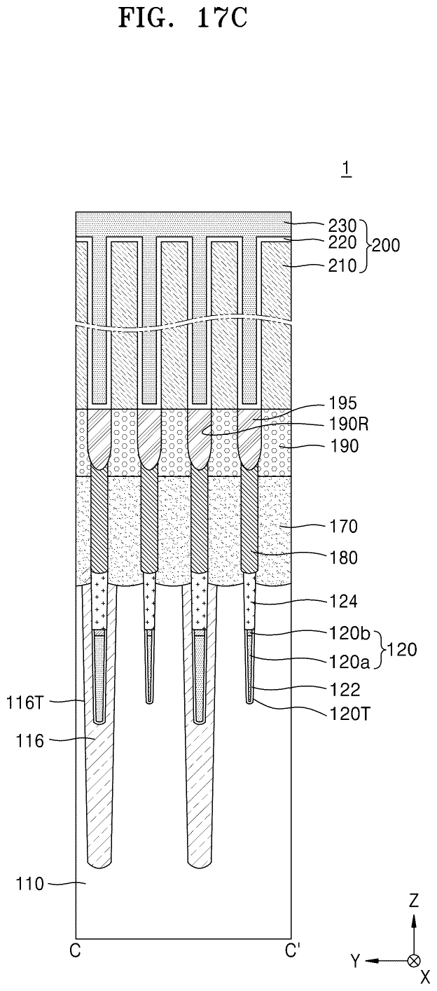

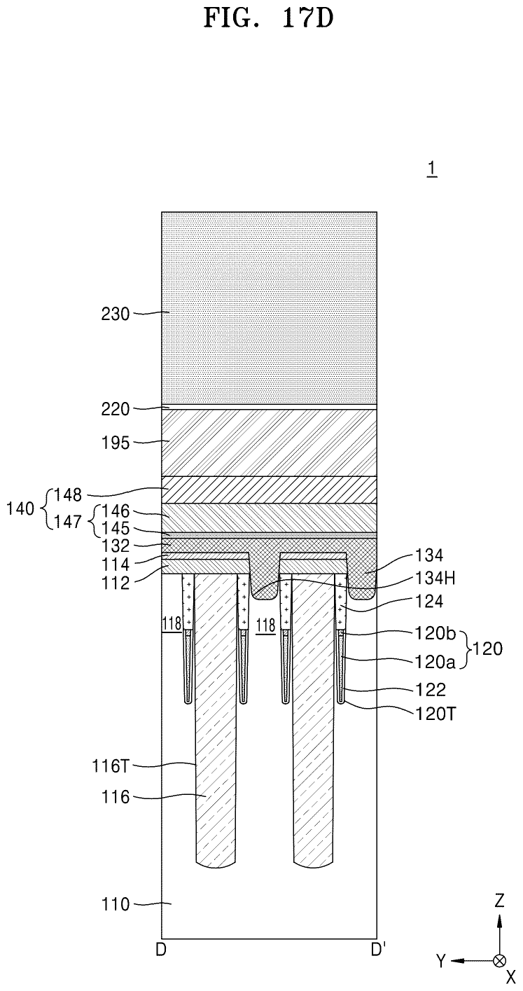

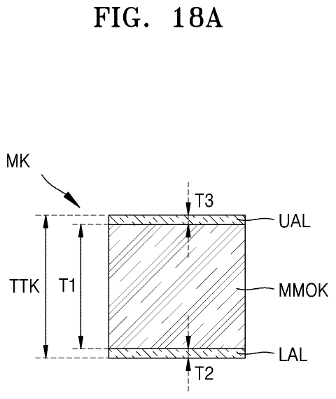

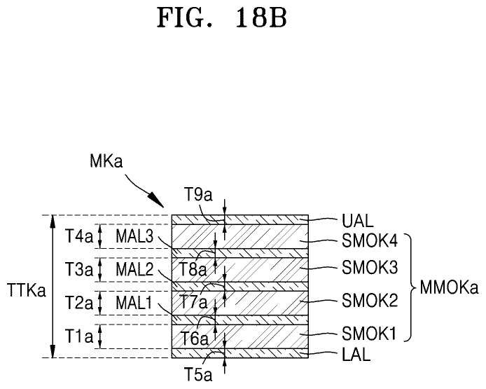

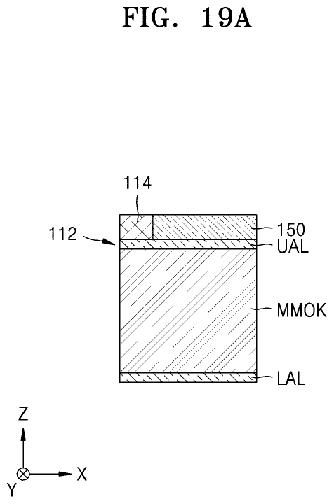

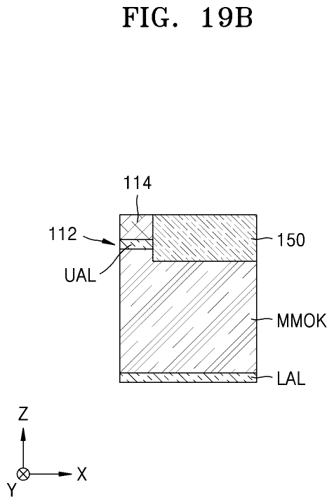

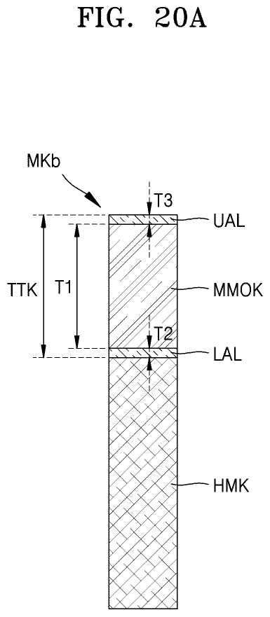

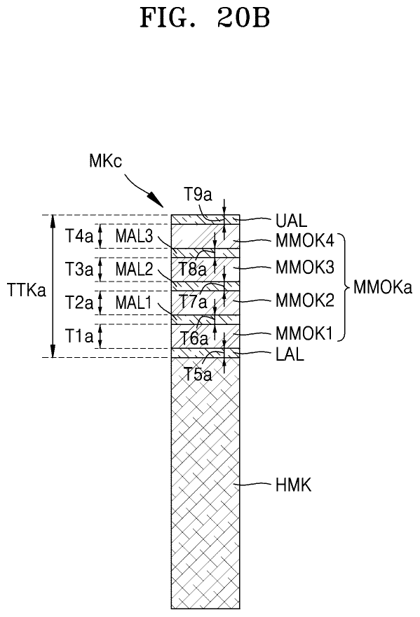

For example, the first mask layer may include an amorphous metal oxide. In some example embodiments, the second mask layer may include an amorphous metal oxide or an amorphous insulating material that does not include metal. The plurality of first mask patterns MKG are described in detail with reference to FIGS. 18A, 18B, 20A, and 20B.

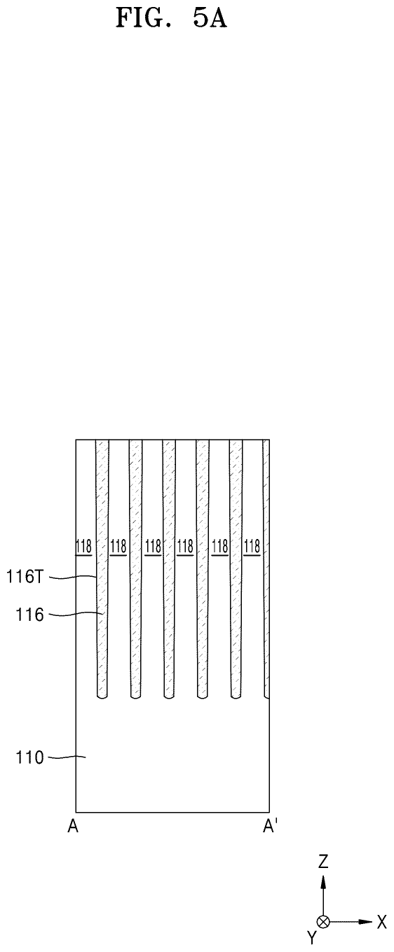

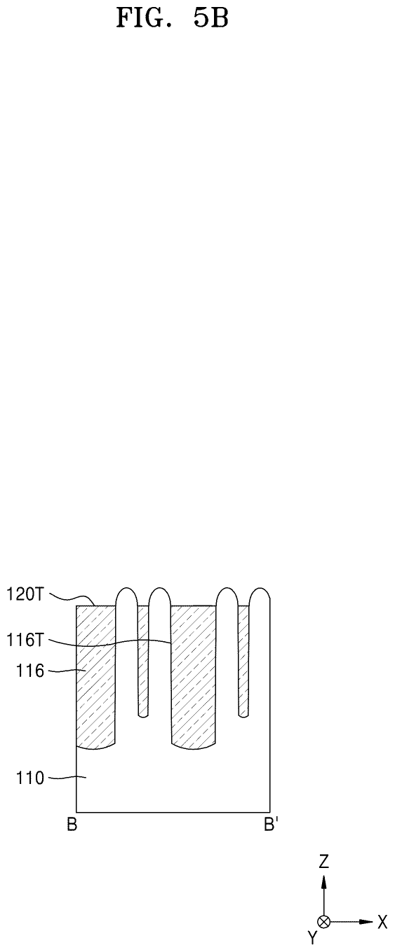

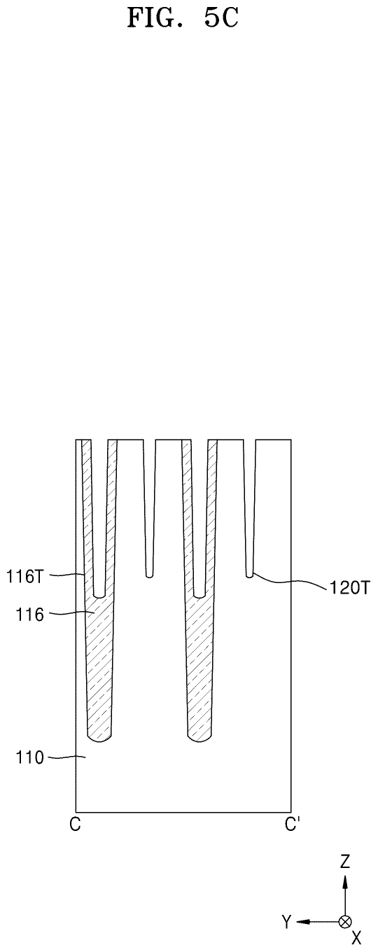

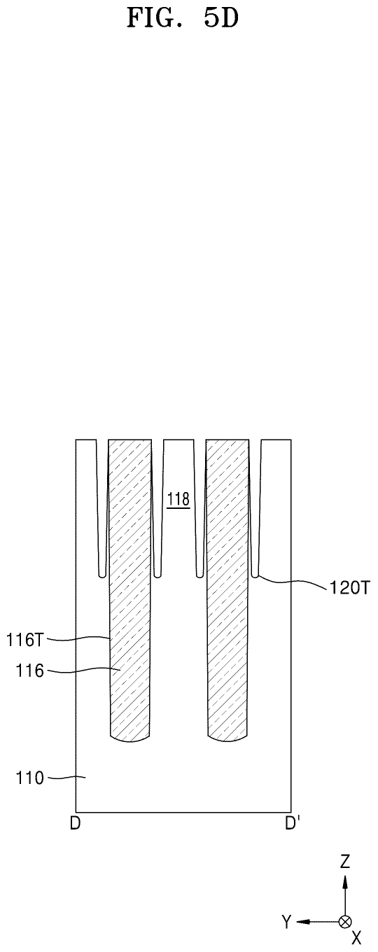

Referring to FIGS. 4A to 4D and FIGS. 5A to 5D together, a portion of the active region 118 exposed on the bottom of the first mask opening MKGO and a portion of the element isolation film 116 are removed using the plurality of first mask patterns MKG as an etch mask, so that a plurality of word line trenches 120T are formed in the substrate 110. After forming the plurality of word line trenches 120T, the plurality of first mask patterns MKG may be removed.

The plurality of word line trenches 120T extend parallel to each other in the first horizontal direction (X direction), and the plurality of word line trenches 120T each may have a line shape and may be disposed to have substantially equal intervals in the second horizontal direction (Y direction) while crossing the active region 118. In some example embodiments, steps may be formed on bottom surfaces of the plurality of word line trenches 120T.

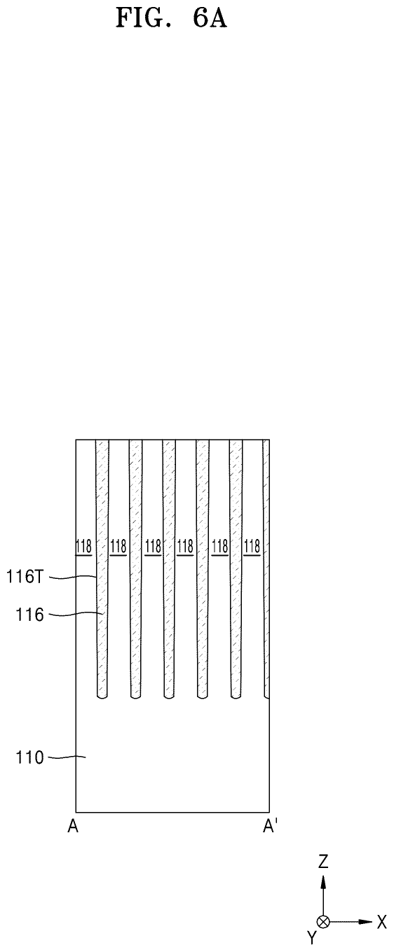

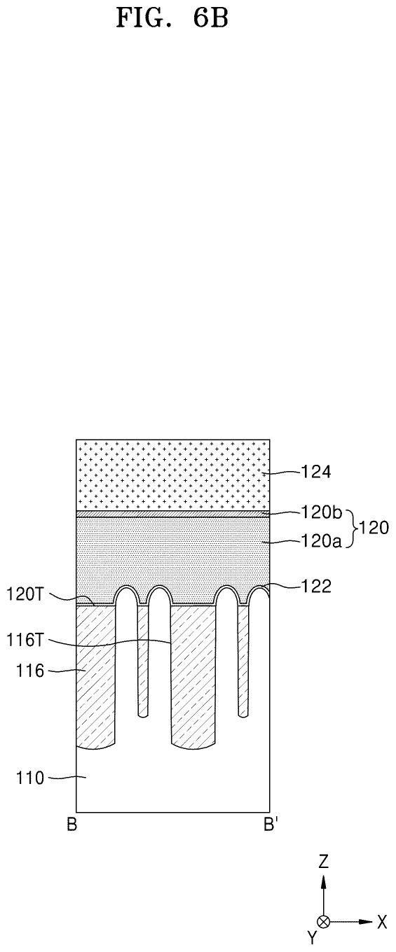

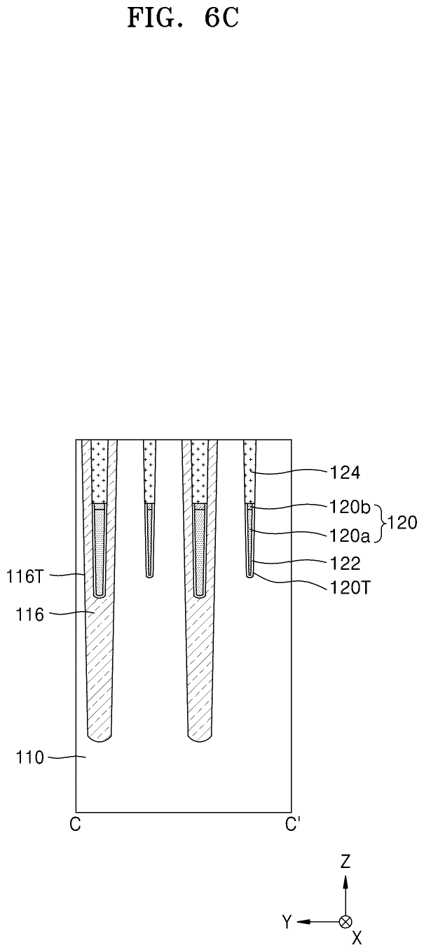

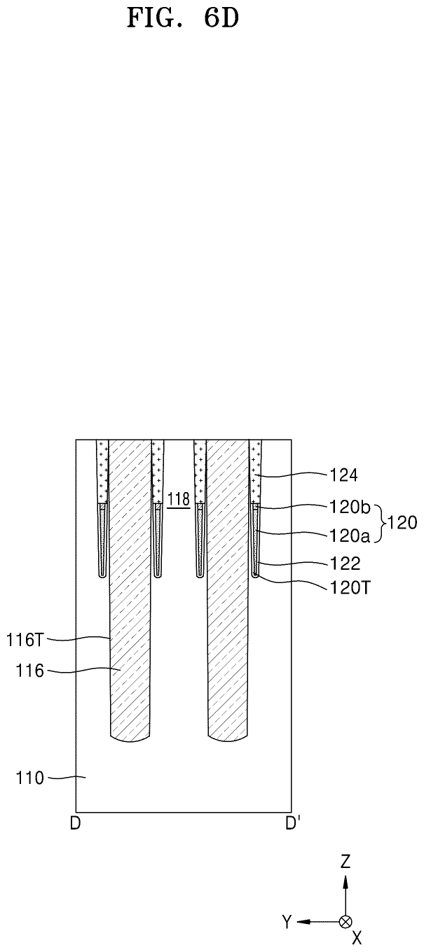

Referring to FIGS. 6A to 6D, a plurality of gate dielectric films 122, a plurality of word lines 120, and a plurality of buried insulating films 124 may be sequentially formed inside the plurality of word line trenches 120T. The plurality of word lines 120 may constitute the plurality of word lines WL illustrated in FIG. 2. The plurality of word lines 120 extend in parallel in the first horizontal direction (X direction), and each of the plurality of word lines 120 may have a line shape. The plurality of word lines 120 are disposed to have substantially equal intervals in the second horizontal direction (Y direction) while crossing the active region 118. A top surface of each of the plurality of word lines 120 may be at a level lower than the top surface of the substrate 110. Bottom surfaces of the plurality of word lines 120 may have concave-convex shapes, and saddle fin structure transistors (e.g., saddle fin field-effect transistors (FinFETs)) may be formed in the plurality of active regions 118.

In this specification, a level or a vertical level refers to a height in the vertical direction (Z direction) with respect to the main surface or upper surface of the substrate 110. That is, being located at the same level or at a constant level refers to a position having the same or constant height in the vertical direction (Z direction) with respect to the main surface or upper surface of the substrate 110, and being located at a low/high level refers to a position having a low/high height in the vertical direction (Z direction) with respect to the main surface of the substrate 110.

Each of the plurality of word lines 120 may have a stacked structure of a lower word line layer 120a and an upper word line layer 120b. For example, the lower word line layer 120a may be formed of a metal material, a conductive metal nitride, or a combination thereof. In some example embodiments, the lower word line layer 120a may be formed of Ti, TiN, Ta, TaN, W, WN, TiSiN, WSiN, or a combination thereof. For example, the upper word line layer 120b may be formed of doped polysilicon. In some example embodiments, the lower word line layer 120a may include a core layer and a barrier layer disposed between the core layer and the gate dielectric film 122.

In some example embodiments, before or after forming the plurality of word lines 120, impurity ions are implanted into the active regions 118 of the substrate 110 on both sides of the plurality of word lines 120, so that a source region and a drain region may be formed in the plurality of active regions 118.

The gate dielectric film 122 may be formed of at least one selected from among silicon oxide, silicon nitride, silicon oxynitride, oxide/nitride/oxide (ONO), and high-k dielectrics having a higher dielectric constant than silicon oxide. For example, the high dielectric film may have a dielectric constant of about 10 to about 25.

Upper surfaces of the plurality of buried insulating films 124 may be at substantially the same level as the upper surface of the substrate 110. The buried insulating films 124 may be made of at least one material selected from silicon oxide, silicon nitride, silicon oxynitride, and a combination thereof.

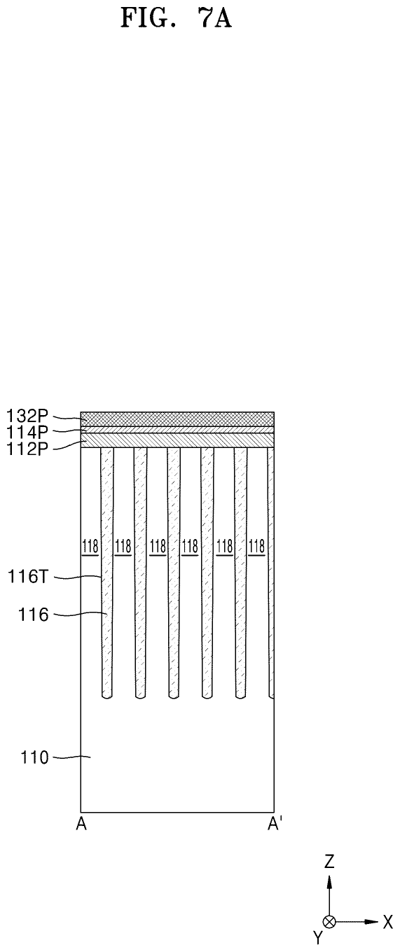

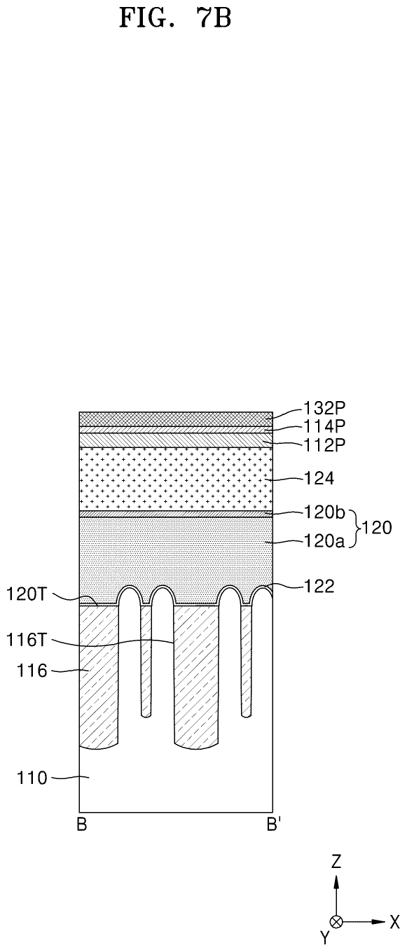

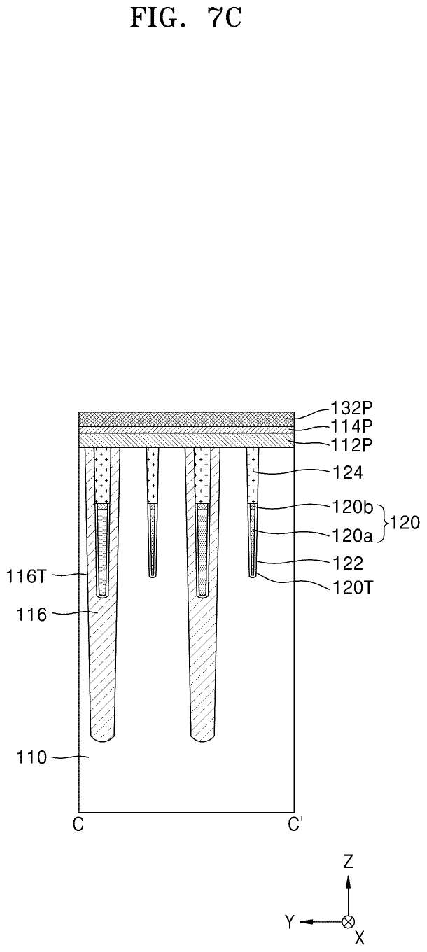

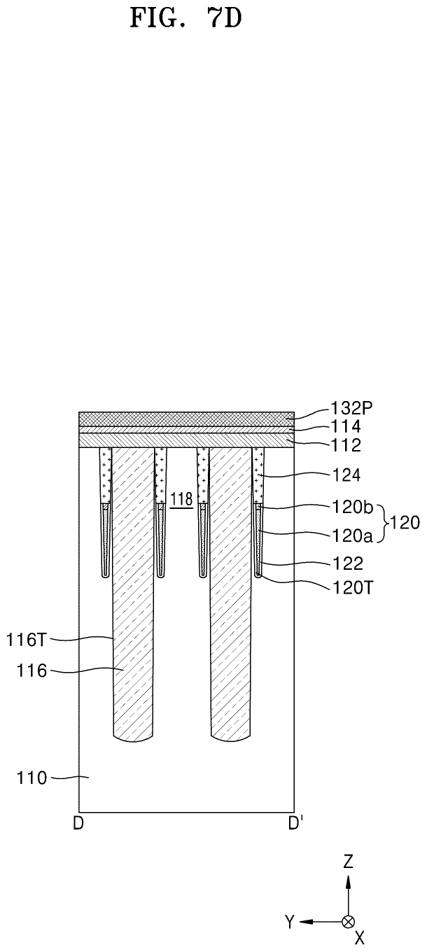

Referring to FIGS. 7A to 7D together, a preliminary mask layer 112P and a preliminary cover insulating layer 114P that cover the element isolation film 116, the plurality of active regions 118, and the plurality of buried insulating films 124 are formed, and a conductive semiconductor layer 132P is formed on the preliminary cover insulating layer 114P.

The preliminary mask layer 112P may be amorphous. The preliminary mask layer 112P may include metal oxide. The preliminary mask layer 112P may have a stacked structure including at least one first mask layer and two or more second mask layers. In some example embodiments, the preliminary mask layer 112P may have a stacked structure in which the first mask layer is disposed between two second mask layers. In some other example embodiments, the preliminary mask layer 112P includes a plurality of first mask layers and a plurality of second mask layers, and the plurality of first mask layers are respectively disposed between two of the second mask layers adjacent to each other in the vertical direction (Z direction) among the plurality of second mask layers, so that the plurality of first mask patterns MKG may have a stacked structure in which a plurality of first mask layers and a plurality of second mask layers are alternately stacked in the vertical direction (Z direction).

For example, the first mask layer may include an amorphous metal oxide. In some example embodiments, the second mask layer may include an amorphous metal oxide or an amorphous insulating material that does not include metal. The preliminary mask layer 112P is described in detail with reference to FIGS. 18A, 18B, 20A, and 20B.

The preliminary cover insulating layer 114P may be formed of silicon nitride, silicon oxynitride, metal oxide, or a combination thereof. The conductive semiconductor layer 132P may be formed of, for example, doped polysilicon.

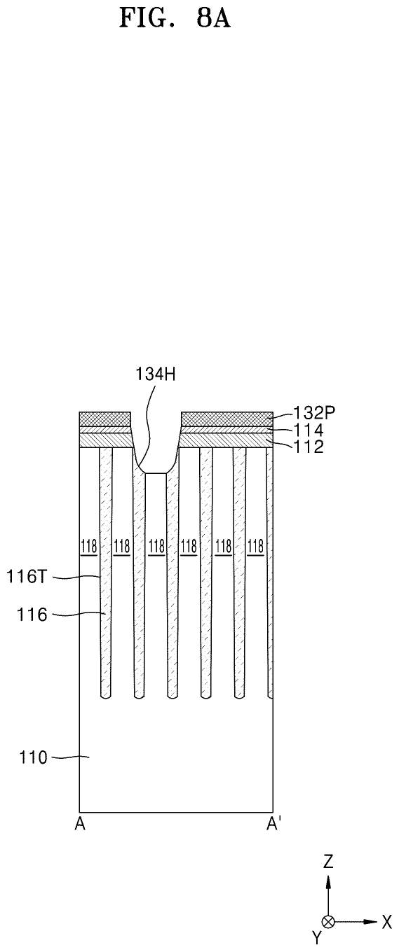

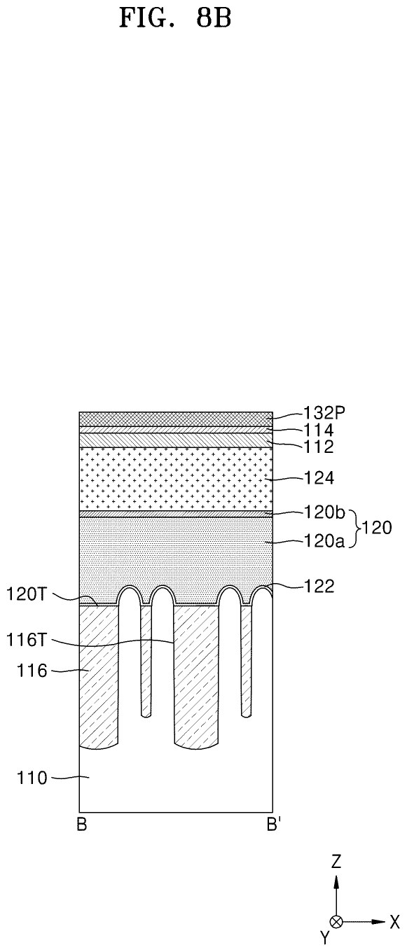

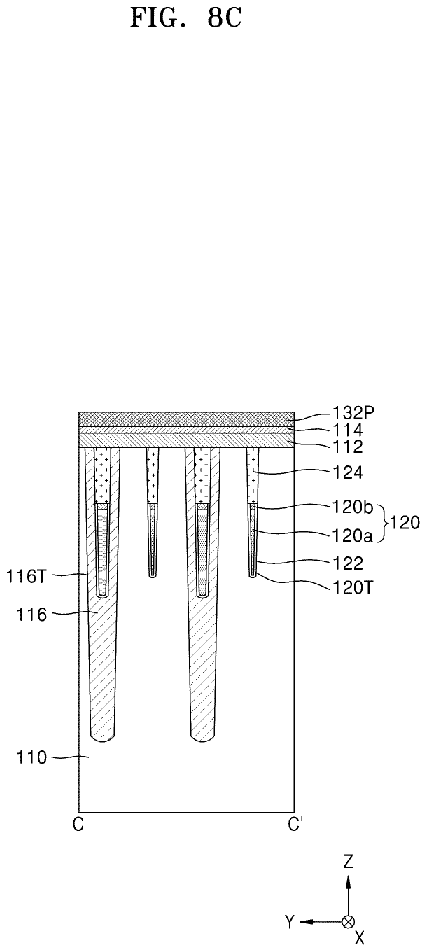

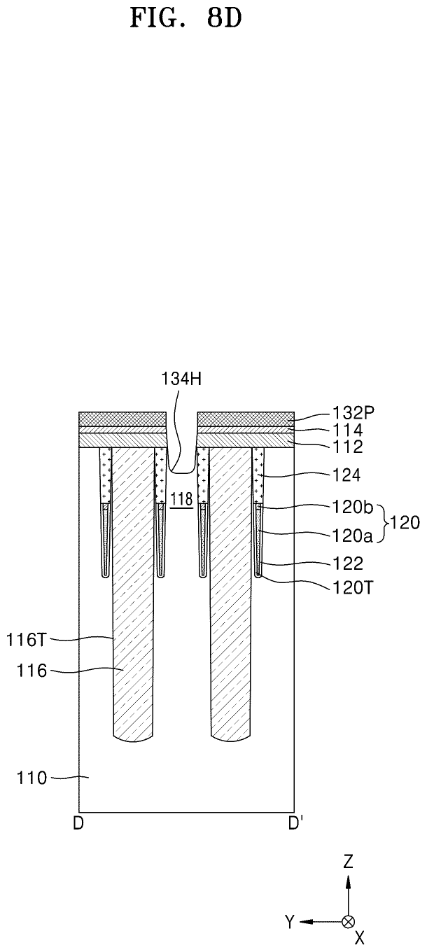

Referring to FIGS. 8A to 8D together, through the conductive semiconductor layer 132P, the preliminary cover insulating layer 114P, and the preliminary mask layer 112P, a plurality of direct contact holes 134H exposing the source region in the active region 118 are formed. In some example embodiments, each of the plurality of direct contact holes 134H may be formed to extend into the active region 118, that is, into the source region. In the process of forming a plurality of direct contact holes 134H, a portion of the preliminary mask layer 112P and a portion of the preliminary cover insulating layer 114P may be removed to form the second mask pattern 112 and the cover insulating film pattern 114. The second mask pattern 112 and the cover insulating film pattern 114 may define a plurality of direct contact holes 134H extending into the active region 118.

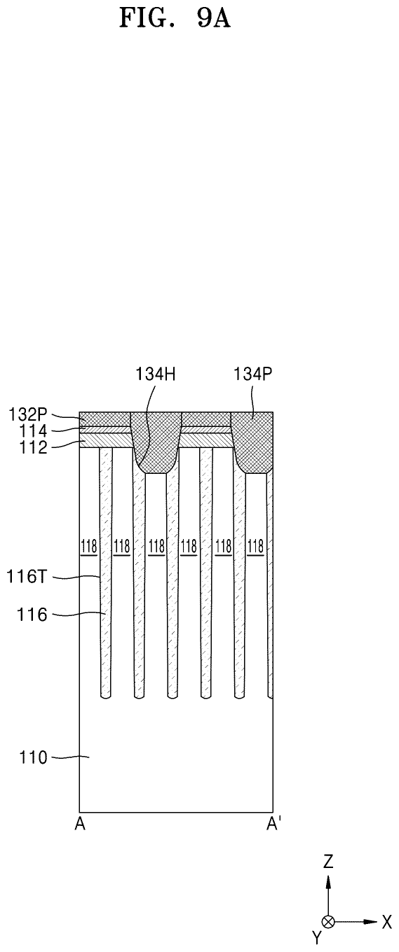

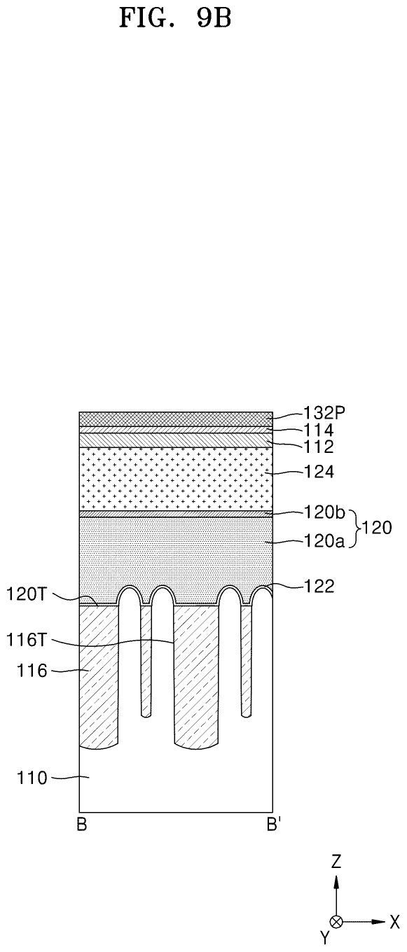

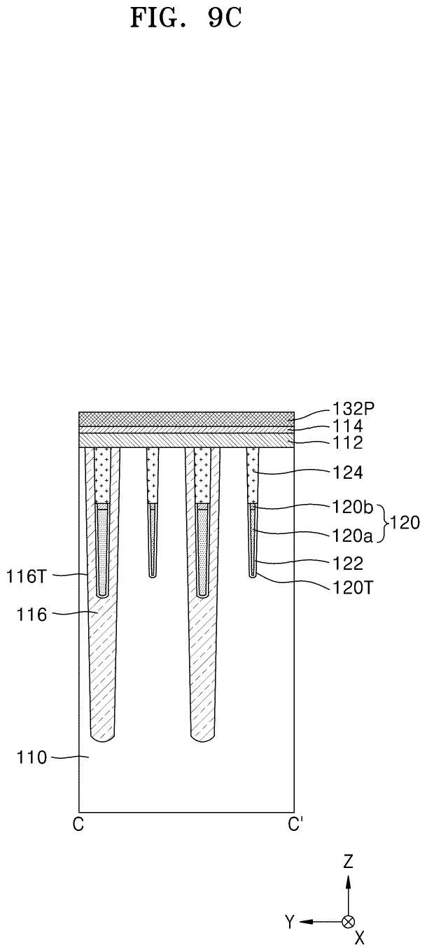

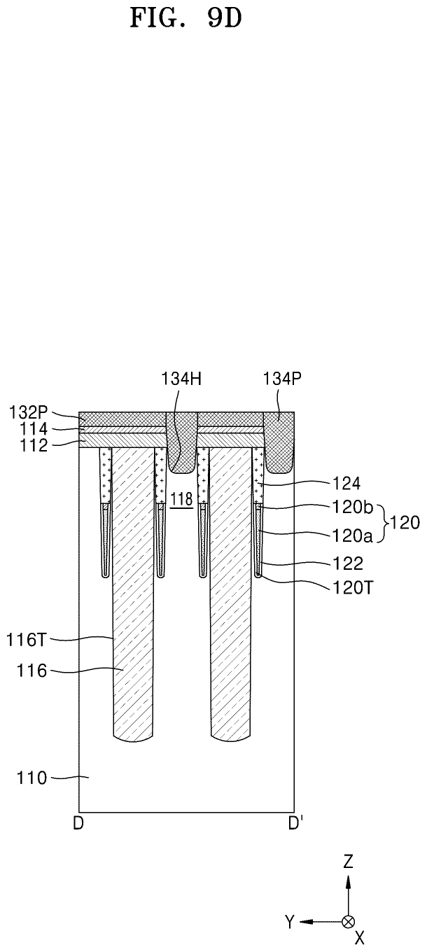

Referring to FIGS. 9A to 9D together, a direct contact conductive layer 134P filling each of the plurality of direct contact holes 134H is formed. The direct contact conductive layer 134P may be made of metal or a metal compound that is a conductive material. For example, the direct contact conductive layer 134P may be formed of a conductive material that is a compound of metal such as Ti and W or a compound of metal such as Ti and W and non-metal such as Si, C, B, and N. In some example embodiments, the direct contact conductive layer 134P may be made of TiN, WC, or WSi.

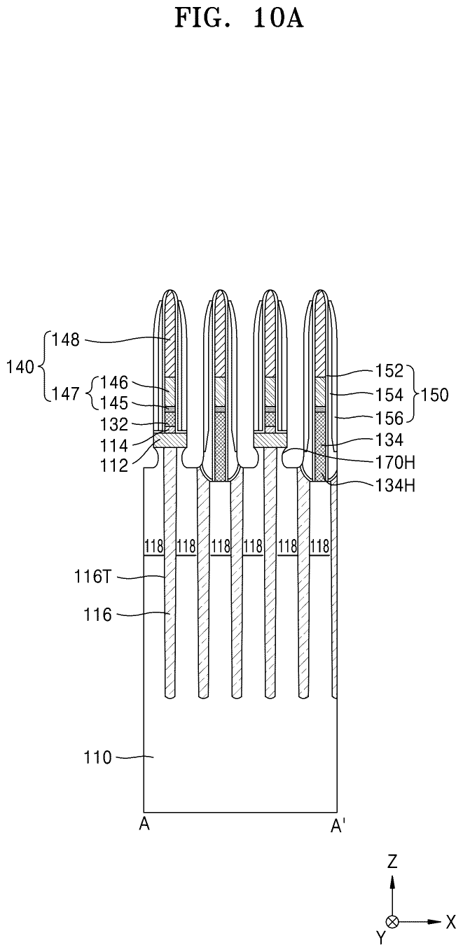

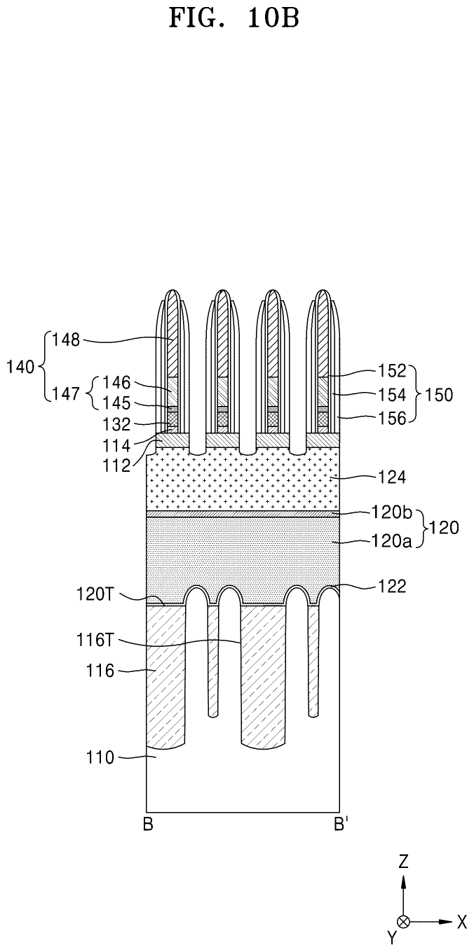

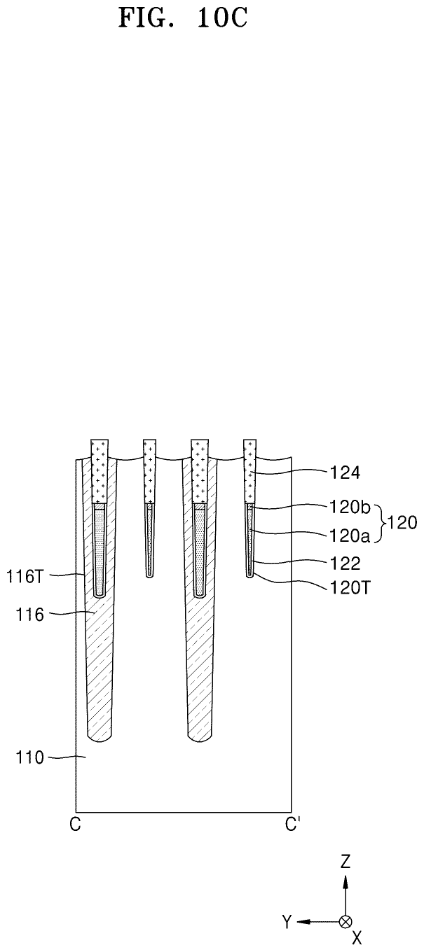

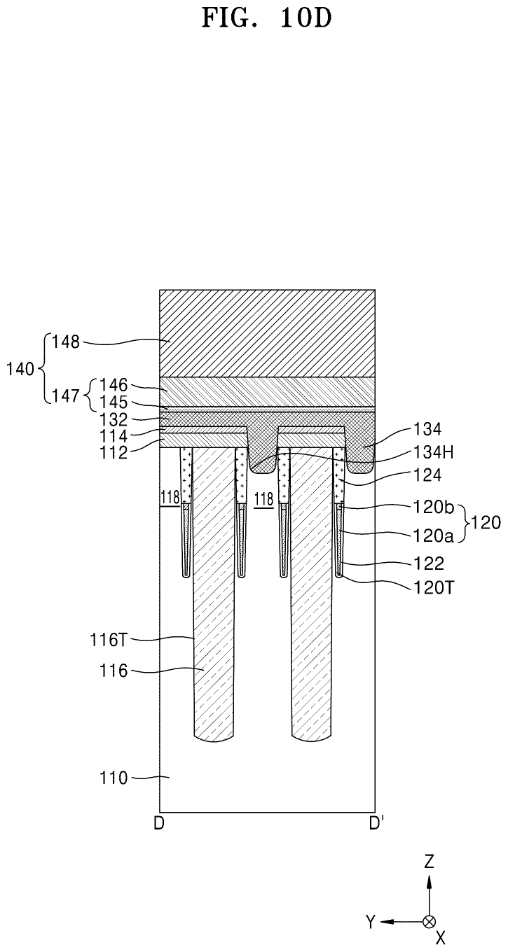

Referring to FIGS. 9A to 9D and FIGS. 10A to 10D together, a metal-based conductive layer and an insulating capping layer covering the conductive semiconductor layer 132P and the direct contact conductive layer 134P are sequentially formed. In some example embodiments, the metal-based conductive layer may have a stacked structure of a first metal-based conductive layer and a second metal-based conductive layer. By etching the first metal-based conductive layer, the second metal-based conductive layer, and the insulating capping layer, a plurality of bit lines 147 and a plurality of insulating capping lines 148 having a stacked structure of line-shaped first metal-based conductive patterns 145 and second metal-based conductive patterns 146 are formed.

In some example embodiments, the line-shaped first metal-based conductive pattern 145 may be made of titanium nitride (TiN) or Ti—Si—N(TSN) and the second metal-based conductive pattern 146 may be made of tungsten (W) or tungsten and tungsten silicide (WSix). In some example embodiments, the first metal-based conductive pattern 145 may function as a diffusion barrier. In some example embodiments, the plurality of insulating capping lines 148 may be made of silicon nitride.

One bit line 147 and one insulating capping line 148 covering the one bit line 147 may constitute one bit line structure 140. The plurality of bit line structures 140 each composed of the bit line 147 and the insulating capping line 148 covering the bit line 147 are parallel to each other in the first horizontal direction parallel to the main surface of the substrate 110 (X direction). The plurality of bit lines 147 may respectively constitute the plurality of bit lines BL illustrated in FIG. 2.

The plurality of conductive semiconductor patterns 132 and the plurality of direct contact conductive patterns 134 may be formed by an etching process using the plurality of bit line structures 140 as an etch mask. Each of the plurality of bit line structures 140 used as an etch mask may be referred to as a mask pattern structure. For example, in the process of forming a plurality of bit line structures 140 composed of a plurality of bit lines 147 and a plurality of insulating capping lines 148 covering the plurality of bit lines 147, an etching process is additionally performed to remove a portion of the conductive semiconductor layer 132P and a portion of the direct contact conductive layer 134P that do not overlap the bit line structure 140 in the vertical direction (Z direction). Thus, a plurality of conductive semiconductor patterns 132 and a plurality of direct contact conductive patterns 134 that are a portion of the conductive semiconductor layer 132P and a portion of the direct contact conductive layer 134P, respectively, overlapping the bit line structure 140 in the vertical direction (Z direction) may be formed. In the etching process of forming the plurality of conductive semiconductor patterns 132 and the plurality of direct contact conductive patterns 134, the second mask pattern 112 may function as an etching mask such that the second mask pattern 112 protects the element isolation film 116 and the plurality of active regions 118 located under the second mask pattern 112 from being removed. The second mask pattern 112 may remain without being removed after the plurality of conductive semiconductor patterns 132 and the plurality of direct contact conductive patterns 134 are formed, and the remaining second mask pattern 112 may be referred to as a mask pattern or a mask pattern layer.

The plurality of direct contact conductive patterns 134 may configure the plurality of direct contacts DC illustrated in FIG. 2. The plurality of bit lines 147 may be electrically connected to the plurality of active regions 118 through the plurality of direct contact conductive patterns 134. For example, each of the plurality of direct contact conductive patterns 134 may be connected to an intermediate connection portion of each of the plurality of active regions 118. In some example embodiments, in the process of forming the plurality of conductive semiconductor patterns 132 and the plurality of direct contact conductive patterns 134, a portion of the cover insulating film pattern 114, which does not overlap the plurality of bit lines 147, may be removed.

In some example embodiments, the bit line structure 140 may further include a conductive semiconductor pattern 132 that is a portion of the conductive semiconductor layer 132P disposed between the cover insulating film pattern 114 and the first metal-based conductive pattern 145.

The conductive semiconductor pattern 132 may be formed of, for example, doped polysilicon. The direct contact conductive pattern 134 may be made of metal or a metal compound that is a conductive material. For example, the direct contact conductive pattern 134 may be formed of a conductive material that is a compound of metal such as Ti and W or a compound of metal such as Ti and W and non-metal such as Si, C, B, and N. In some example embodiments, the direct contact conductive pattern 134 may be made of TiN, WC, or WSi.

The insulating spacer structure 150 may be formed to cover both sidewalls of each of the plurality of bit line structures 140. Each of the plurality of insulating spacer structures 150 may include a first insulating spacer 152, a second insulating spacer 154, and a third insulating spacer 156. The second insulating spacer 154 may be made of a material having a lower permittivity than the first insulating spacer 152 and the third insulating spacer 156. In some example embodiments, the first insulating spacer 152 and the third insulating spacer 156 may be made of nitride and the second insulating spacer 154 may be made of oxide. In some example embodiments, the first insulating spacer 152 and the third insulating spacer 156 may be made of nitride and the second insulating spacer 154 may be made of a material having an etch selectivity with respect to the first insulating spacer 152 and the third insulating spacer 156. For example, when the first insulating spacer 152 and the third insulating spacer 156 are made of nitride, the second insulating spacer 154 is made of oxide and may be removed in a subsequent process to become an air spacer.

A plurality of buried contact holes 170H may be formed between each of the plurality of bit line structures 140. An inner space of the plurality of buried contact holes 170H may be limited by the insulating spacer structure 150 covering the sidewall of each of the two neighboring bit lines 147 among the plurality of bit lines 147 and the active region 118.

By using the plurality of insulating capping lines 148 and the insulating spacer structure 150 covering both sidewalls of each of the plurality of bit line structures 140 as an etch mask, the plurality of buried contact holes 170H may be formed by removing portions of the second mask pattern 112 and the active region 118. In some example embodiments, by using the plurality of insulating capping lines 148 and the insulating spacer structure 150 covering both sidewalls of each of the plurality of bit line structures 140 as an etch mask, after first performing an anisotropic etching process to remove portions of the second mask pattern 112 and the active region 118, an isotropic etching process is performed to further remove other parts of the active region 118, so that the plurality of buried contact holes 170H may be formed to expand a space limited by the active region 118.

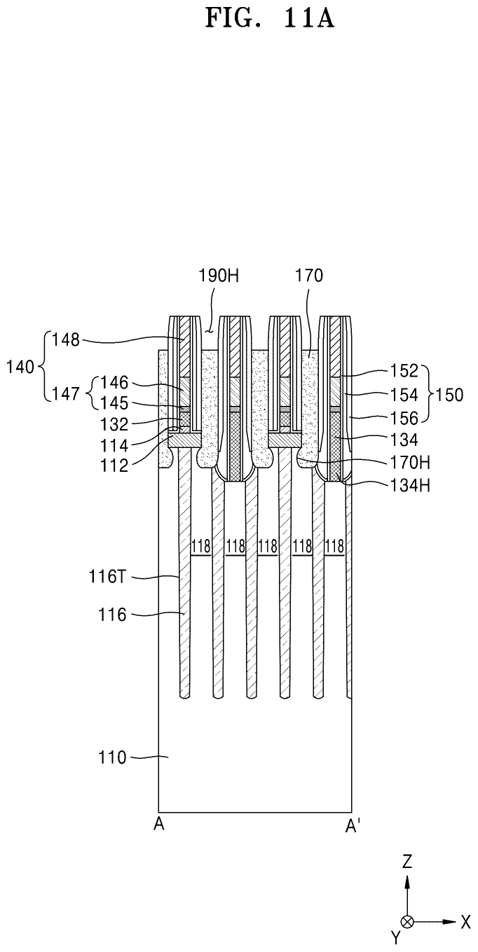

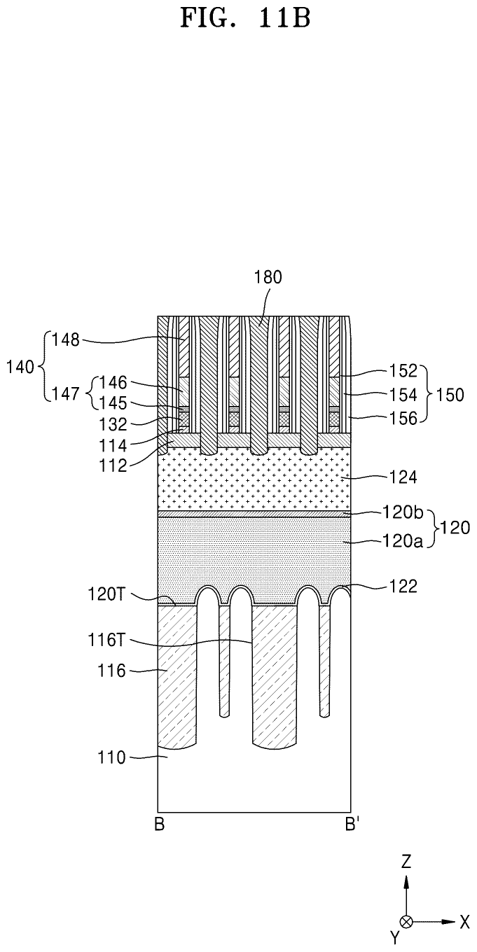

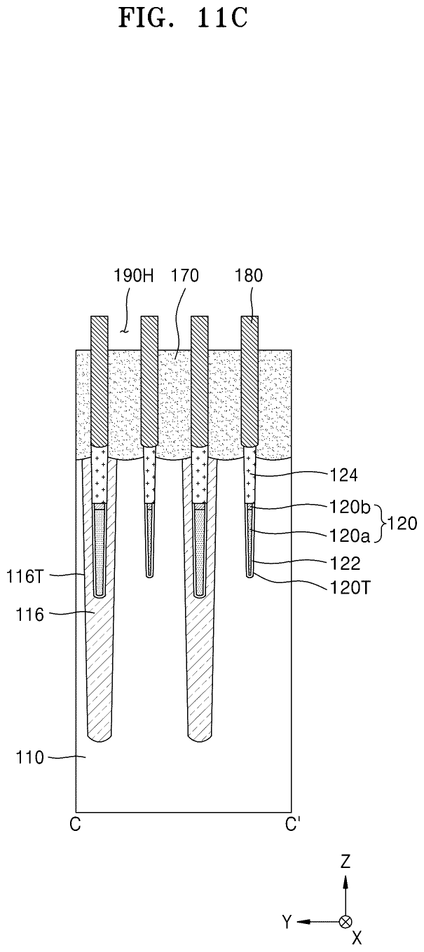

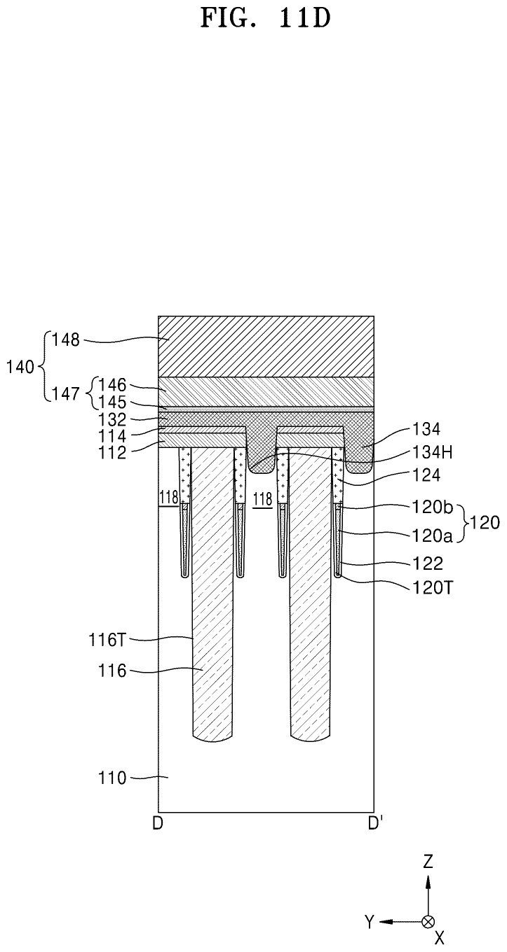

Referring to FIGS. 11A to 11D together, a plurality of buried contacts 170 and a plurality of insulating fences 180 are formed in spaces between the plurality of insulating spacer structures 150 covering both sidewalls of each of the plurality of bit line structures 140. The plurality of buried contacts 170 and the plurality of insulating fences 180 may be alternately disposed along between a pair of insulating spacer structures 150 facing each other among the plurality of insulating spacer structures 150 covering both sidewalls of the plurality of bit line structures 140, that is, in the second horizontal direction (Y direction). For example, the plurality of buried contacts 170 may be made of polysilicon. For example, the plurality of insulation fences 180 may be made of nitride.

In some example embodiments, the plurality of buried contacts 170 may be arranged in a line in each of the first horizontal direction (X direction) and the second horizontal direction (Y direction). Each of the plurality of buried contacts 170 may extend from the active region 118 in the vertical direction (Z direction) perpendicular to the substrate 110. The plurality of buried contacts 170 may constitute the plurality of buried contacts BC illustrated in FIG. 2, respectively.

The plurality of buried contacts 170 may be disposed in a space defined by the plurality of insulating fences 180 and the plurality of insulating spacer structures 150 covering both sidewalls of the plurality of bit line structures 140. The plurality of buried contacts 170 may fill a lower portion of a space between the plurality of insulating spacer structures 150 covering both sidewalls of each of the plurality of bit line structures 140.

A level of upper surfaces of the plurality of buried contacts 170 may be lower than a level of upper surfaces of the plurality of insulating capping lines 148. Upper surfaces of the plurality of insulating fences 180 and upper surfaces of the plurality of insulating capping lines 148 may be at the same level in the vertical direction (Z direction).

A plurality of landing pad holes 190H may be defined by a plurality of insulating spacer structures 150 and a plurality of insulating fences 180. A plurality of buried contacts 170 may be disposed in the plurality of landing pad holes 190H.

In the process of forming the plurality of buried contacts 170 and/or the plurality of insulating fences 180, the insulating capping line 148 included in the bit line structure 140 and the upper portion of the insulating spacer structure 150 are removed, so that a level of an upper surface of the bit line structure 140 may be lowered.

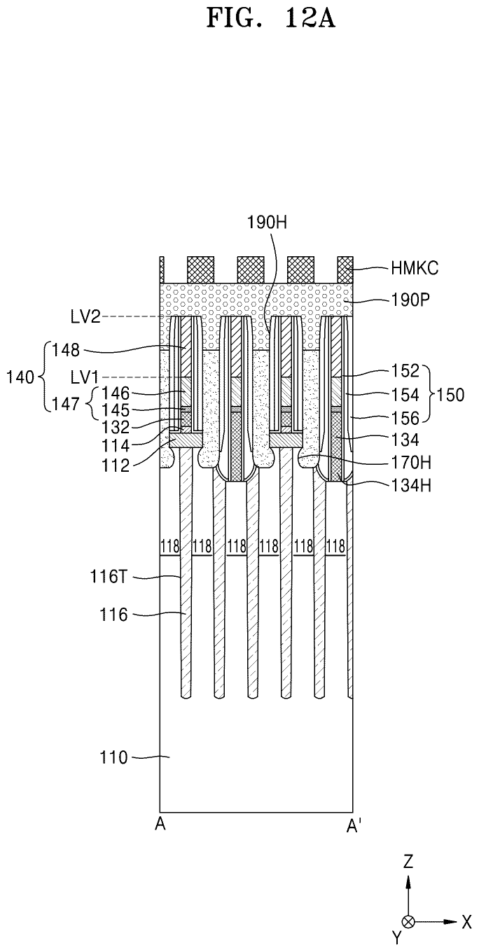

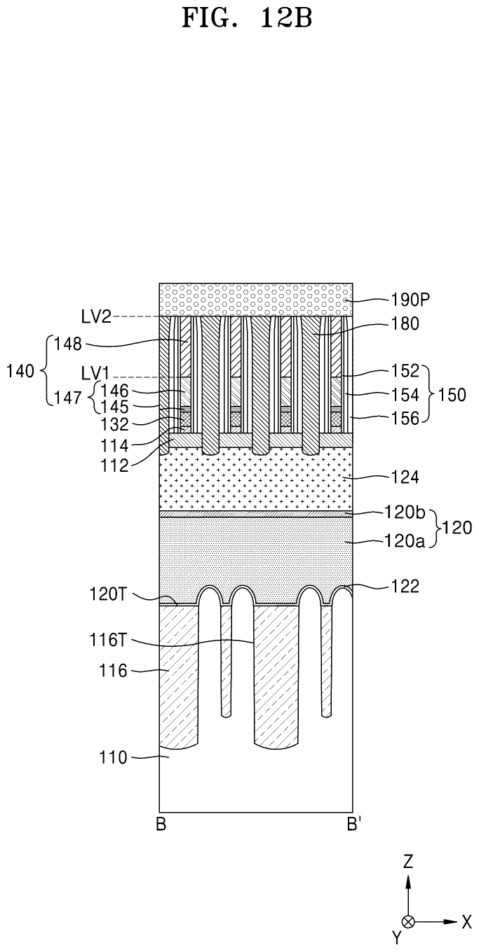

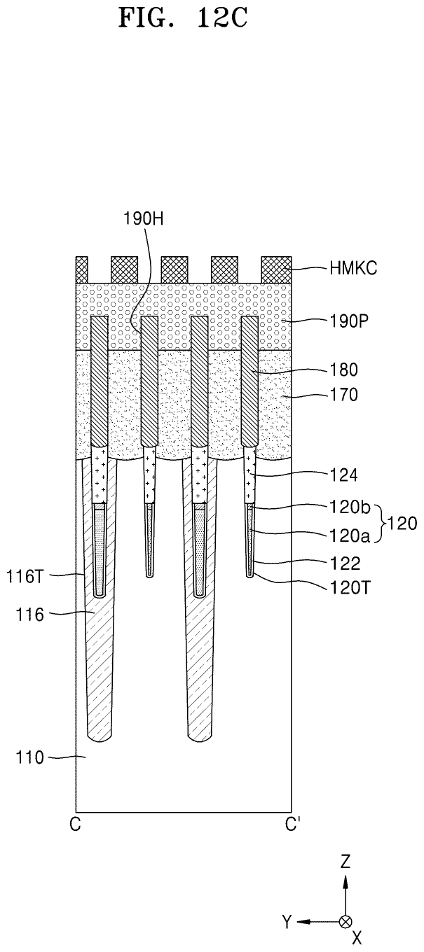

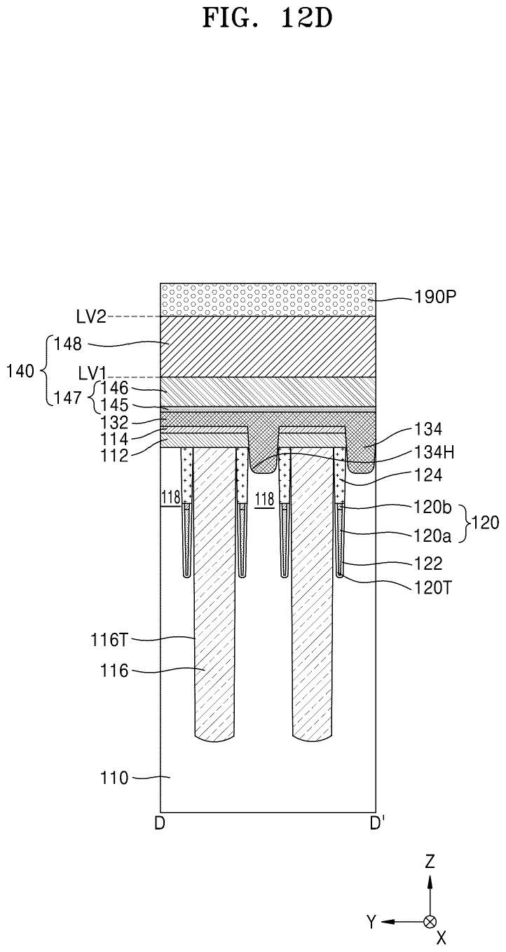

Referring to FIGS. 12A to 12D, a landing pad material layer 190P is formed to fill the plurality of landing pad holes 190H and cover the plurality of bit line structures 140. In some example embodiments, an interface between the buried contact 170 and the landing pad material layer 190P may be higher than the first vertical level LV1 of the upper surface of the second metal-based conductive pattern 146 and lower than the second vertical level LV2 of the upper surface of the insulating capping line 148.

In some example embodiments, the landing pad material layer 190P may include a conductive barrier film and a conductive pad material layer on the conductive barrier film. For example, the conductive barrier film may be made of metal, conductive metal nitride, or a combination thereof. In some example embodiments, the conductive barrier film may be formed of a Ti/TiN stack structure. In some example embodiments, the conductive pad material layer may include tungsten (W).

In some example embodiments, a metal silicide film may be formed on the plurality of buried contacts 170 before forming the landing pad material layer 190P. The metal silicide film may be disposed between the plurality of buried contacts 170 and the landing pad material layer 190P. The metal silicide film may be made of cobalt silicide (CoSix), nickel silicide (NiSix), or manganese silicide (MnSix) but is not limited thereto.

A plurality of hard mask patterns HMKC are formed on the landing pad material layer 190P. In some example embodiments, the plurality of hard mask patterns HMKC may be formed through an EUV lithography process.

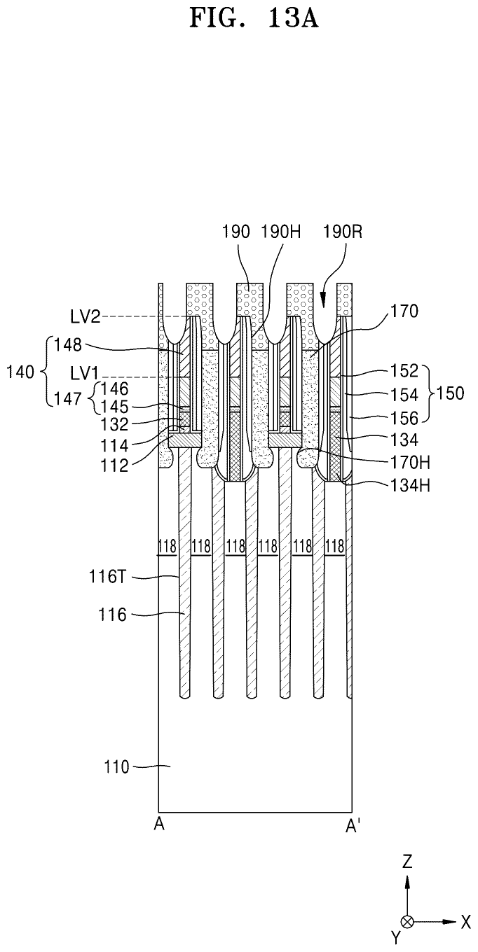

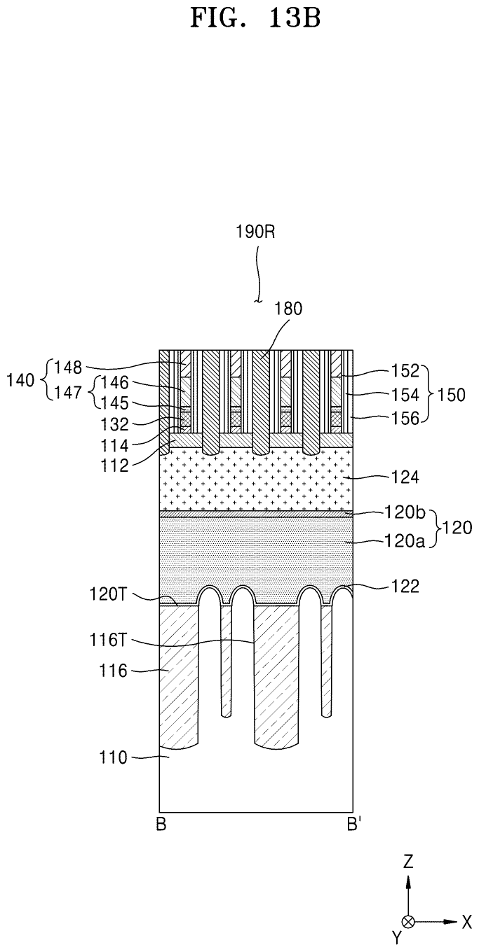

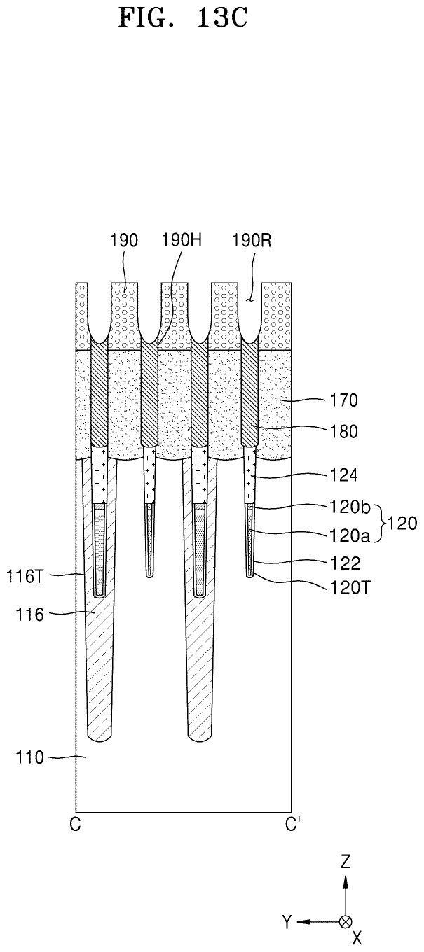

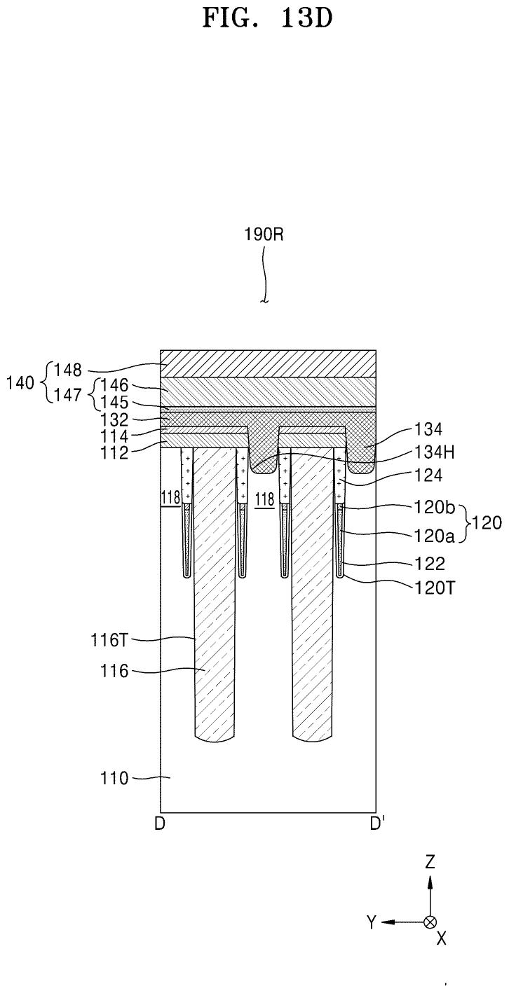

Referring to FIGS. 12A to 12D and FIGS. 13A to 13D together, a portion of the landing pad material layer 190P is removed using the plurality of hard mask patterns HMKC as an etch mask, so that a plurality of landing pads 190 filling at least a portion of the plurality of landing pad holes 190H, extending onto the plurality of bit line structures 140 and separated from each other by a recess portion 190R, are formed.

The plurality of landing pads 190 may be spaced apart from each other with a recess portion 190R disposed therebetween. The plurality of landing pads 190 may be disposed on the plurality of buried contacts 170 and may extend onto the plurality of bit line structures 140. In some example embodiments, the plurality of landing pads 190 may extend onto the plurality of bit lines 147. The plurality of landing pads 190 are disposed on the plurality of buried contacts 170, and the plurality of buried contacts 170 may be electrically connected to corresponding ones of to the plurality of landing pads 190, respectively. The buried contact 170 and the landing pad 190 corresponding to each other may be referred to as a contact plug. The plurality of landing pads 190 may be connected to the active region 118 through a plurality of buried contacts 170. The plurality of landing pads 190 may constitute the plurality of landing pads LP illustrated in FIG. 2.

The buried contact 170 may be disposed between two adjacent bit line structures 140, and the landing pad 190 may extend onto one bit line structure 140 from among two bit line structures 140 adjacent to each other with the buried contact 170 therebetween.

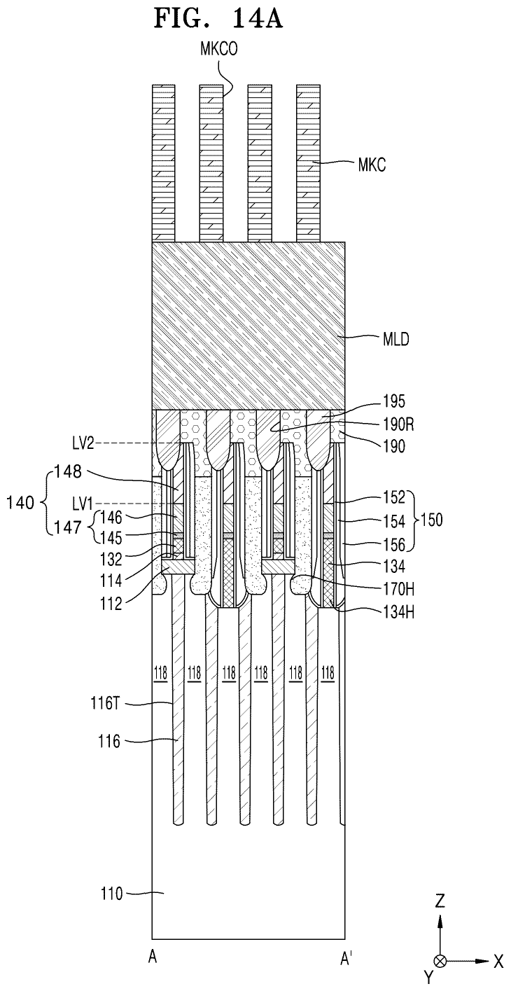

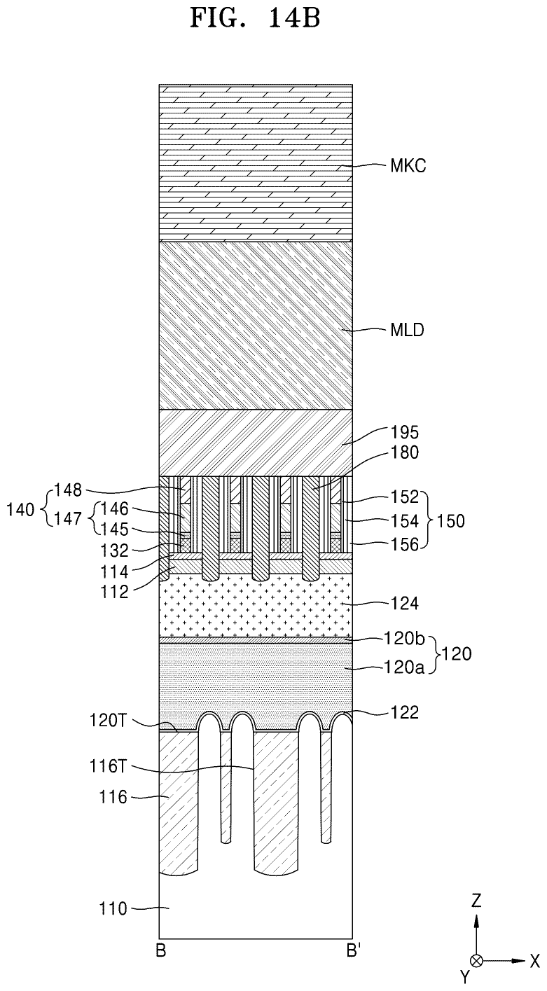

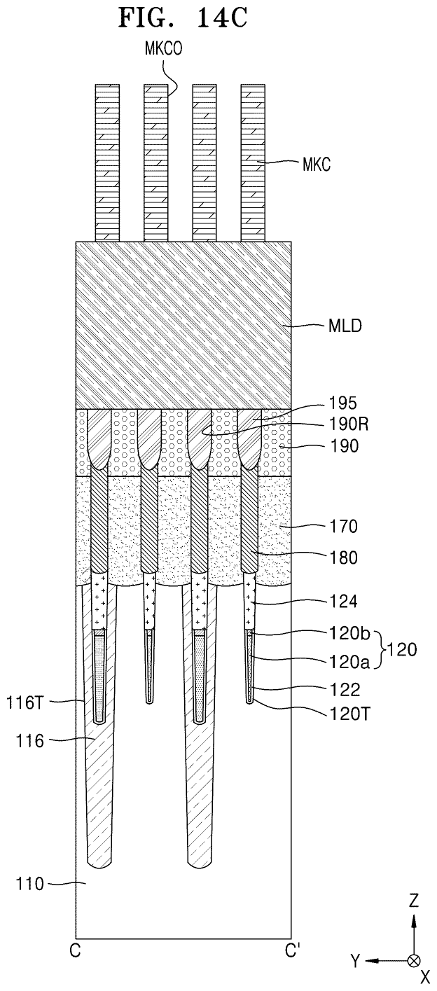

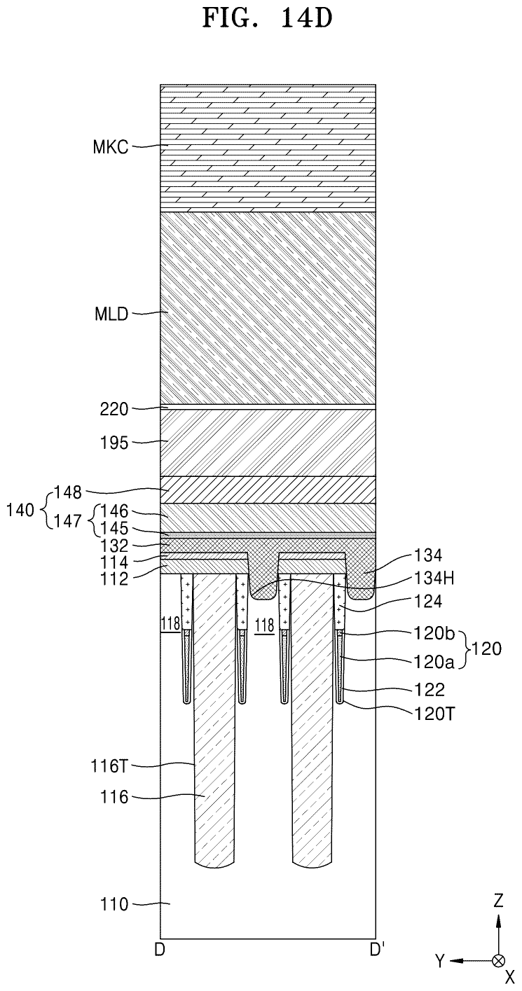

Referring to FIGS. 14A to 14D together, an insulating structure 195 filling the recess portion 190R may be formed. In some example embodiments, the insulating structure 195 may include an interlayer insulating layer and an etch stop layer. For example, the interlayer insulating layer may be made of oxide and the etch stop film may be made of nitride. In FIGS. 14A and 14C, the upper surface of the insulating structure 195 and the upper surface of the landing pad 190 are shown to be at the same level, but example embodiments are not limited thereto.

After forming the mold layer MLD on the plurality of landing pads 190 and the insulating structure 195, a third mask pattern MKC having a plurality of third mask openings MKCO is formed on the mold layer MLD. The plurality of third mask openings MKCO may be disposed to overlap the plurality of landing pads 190 in the vertical direction (Z direction). In some example embodiments, an etch stop film may be formed on the plurality of landing pads 190 and the insulating structure 195 before forming the mold layer MLD.

The third mask pattern MKC may be amorphous. The third mask pattern MKC may include metal oxide. The third mask pattern MKC may have a stacked structure including at least one first mask layer and two or more second mask layers. In some example embodiments, the third mask pattern MKC may have a stacked structure in which the first mask layer is disposed between two second mask layers. In some other example embodiments, the third mask pattern MKC includes a plurality of first mask layers and a plurality of second mask layers, and a plurality of the first mask layers are respectively disposed between two of the second mask layers adjacent to each other in the vertical direction (Z direction) among the plurality of second mask layers, so that the plurality of first mask patterns MKG may have a stacked structure in which a plurality of first mask layers and a plurality of second mask layers are alternately stacked in the vertical direction (Z direction).

For example, the first mask layer may include an amorphous metal oxide. In some example embodiments, the second mask layer may include an amorphous metal oxide or an amorphous insulating material that does not include metal. The third mask pattern MKC is described in detail with reference to FIGS. 18A, 18B, 20A, and 20B.

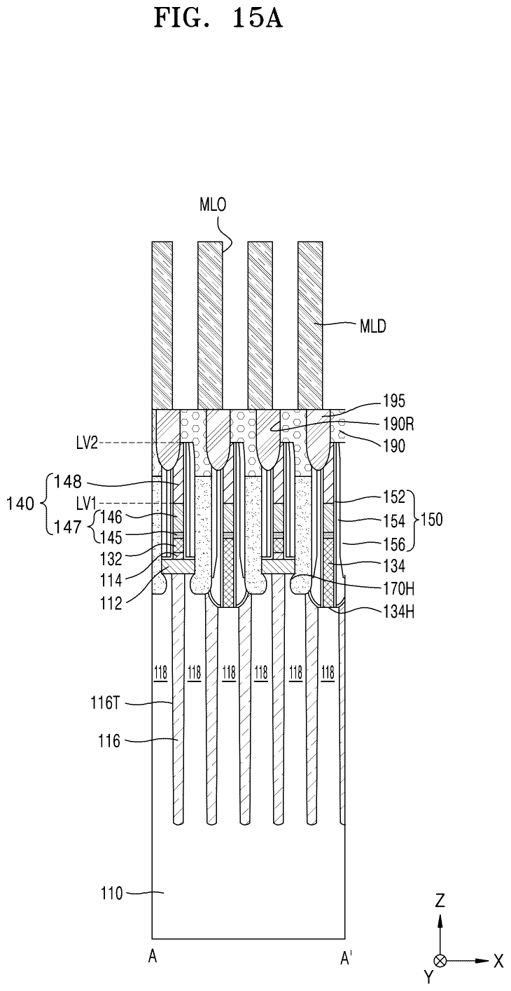

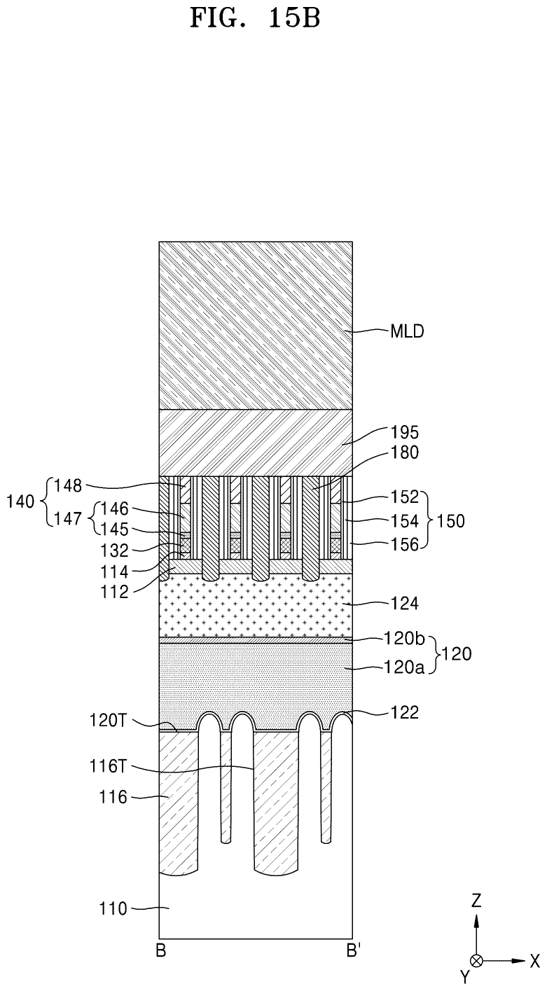

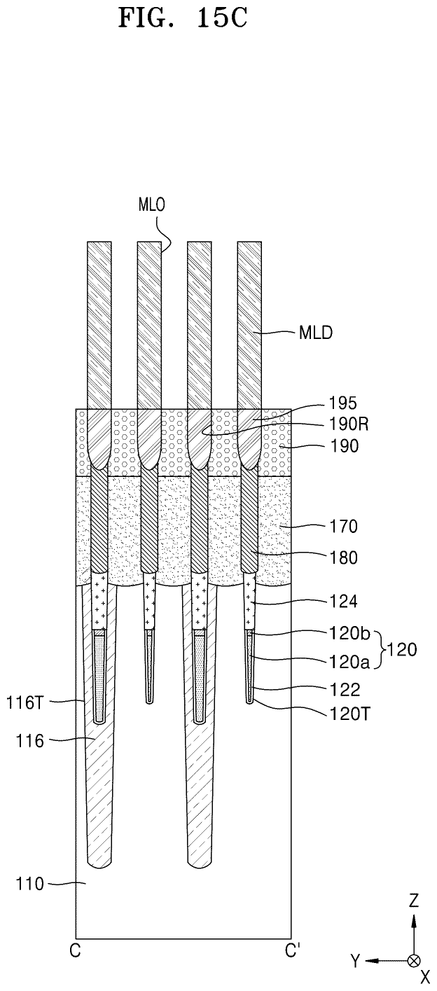

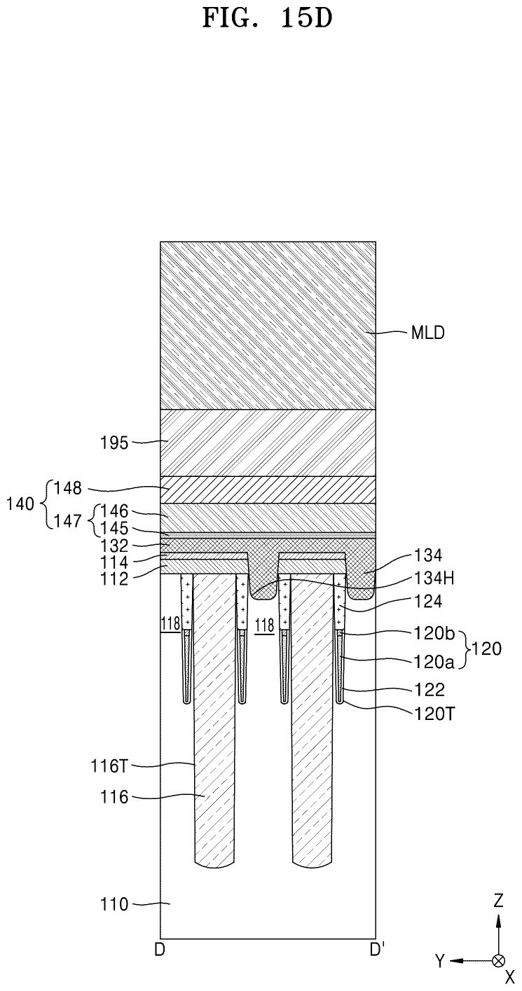

Referring to FIGS. 14A to 14D and FIGS. 15A to 15D together, a plurality of mold openings MLO are formed in the mold layer MLD by etching the mold layer MLD using the third mask pattern MKC as an etch mask. A plurality of landing pads 190 may be exposed on the lower surface of the mold opening MLO. In some example embodiments, when an etch stop film is formed on the plurality of landing pads 190 and the insulating structure 195 before forming the mold layer MLD, after forming a plurality of mold openings MLO, the plurality of landing pads 190 may be exposed by removing portions of the etch stop film exposed on the bottom surfaces of the plurality of mold openings MLO. In some example embodiments, after forming the plurality of mold openings MLO, the third mask pattern MKC may be removed.

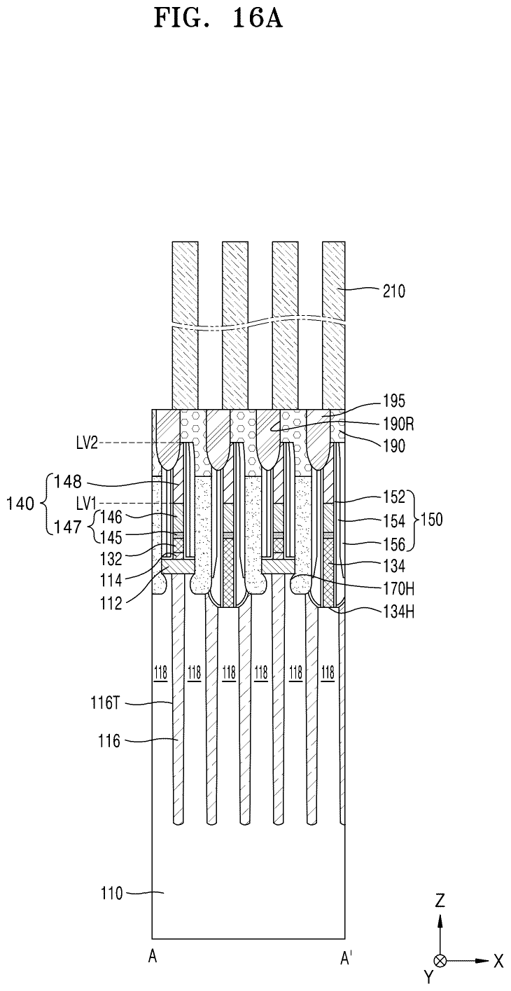

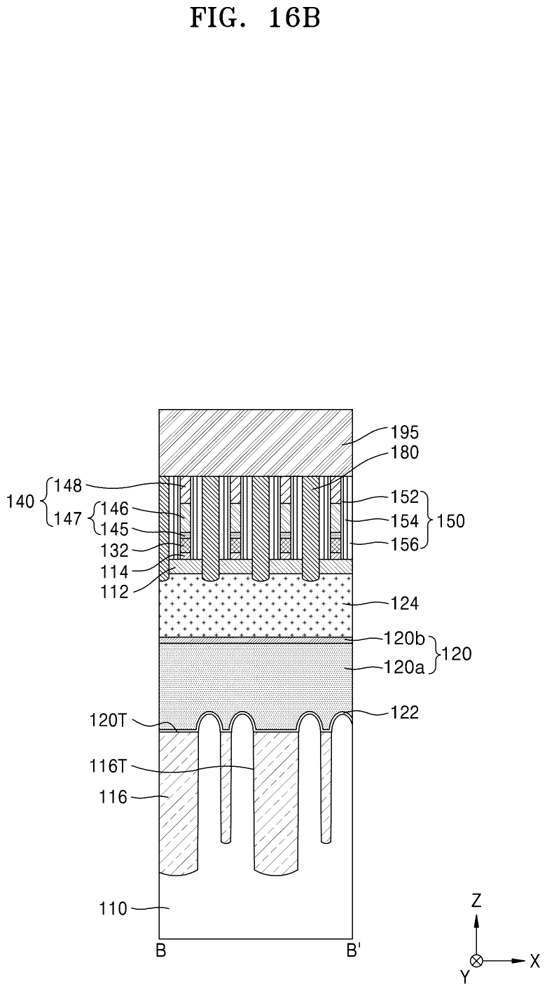

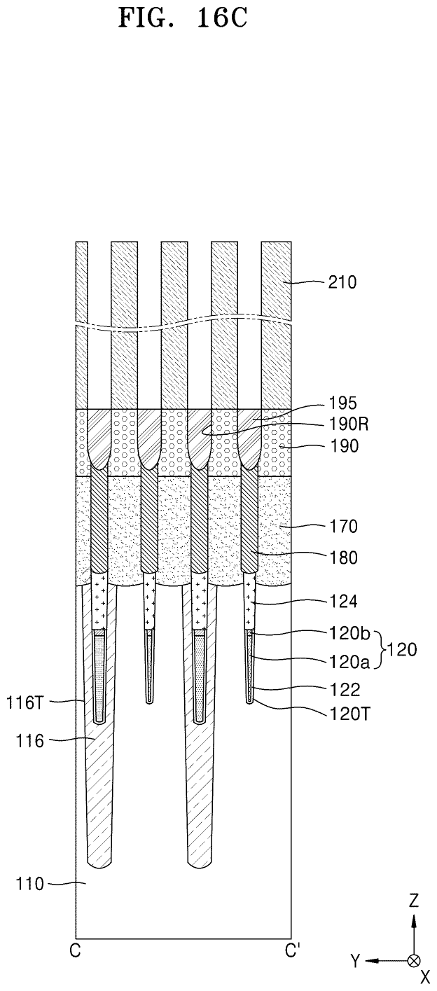

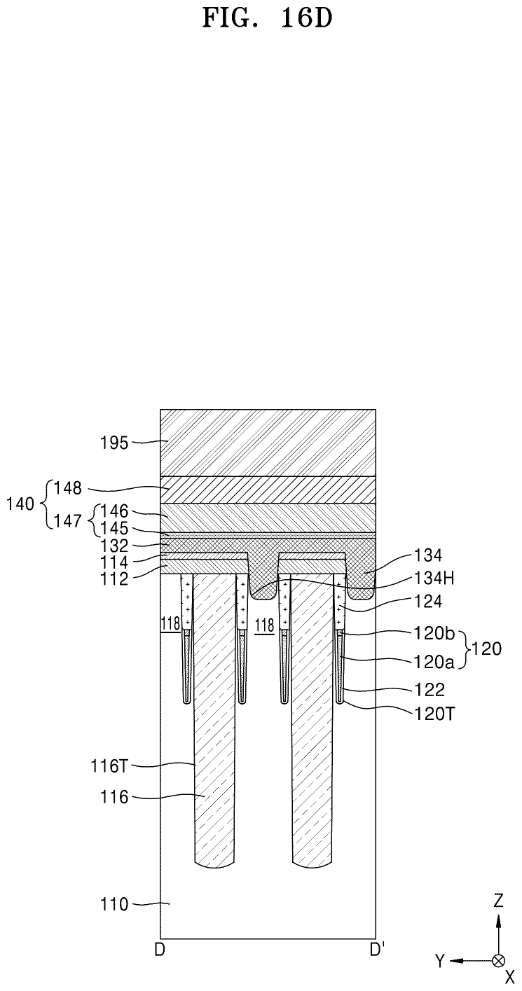

Referring to FIGS. 15A to 15D and FIGS. 16A to 16D together, a plurality of lower electrodes 210 are formed to fill the plurality of mold openings MLO and to be connected to the plurality of landing pads 190. Each of the plurality of lower electrodes 210 may be electrically connected to a corresponding one of the plurality of landing pads 190. Each of the plurality of lower electrodes 210 may have a pillar shape (e.g., a column shape filled inside and having a circular horizontal cross-section), but example embodiments are not limited thereto. In some example embodiments, each of the plurality of lower electrodes 210 may have a cylindrical shape with a lower portion closed. In some example embodiments, the plurality of lower electrodes 210 may be arranged in a honeycomb arrangement in a zigzag pattern with respect to the first horizontal direction (X direction) or the second horizontal direction (Y direction). In some other example embodiments, the plurality of lower electrodes 210 may be arranged in a matrix form arranged in a row in each of the first horizontal direction (X direction) and the second horizontal direction (Y direction). The plurality of lower electrodes 210 may be formed of, for example, impurity-doped silicon, metal such as tungsten or copper, or a conductive metal compound such as titanium nitride. After forming the plurality of lower electrodes 210, the mold layer MLD may be removed. In some example embodiments, the third mask pattern MKC shown in FIGS. 14A to 14D may be removed after forming the plurality of lower electrodes 210.

Referring to FIGS. 17A to 17D, the semiconductor device 1 is formed by sequentially forming a capacitor dielectric layer 220 and an upper electrode 230 on the plurality of lower electrodes 210. The capacitor dielectric layer 220 may conformally cover surfaces of the plurality of lower electrodes 210. In some example embodiments, the capacitor dielectric layer 220 may be integrally formed to cover the plurality of lower electrodes 210 together in a certain region, for example, in one memory cell region CR (see FIG. 2).

The capacitor dielectric layer 220 may be formed, for example, TaO, TaAlO, TaON, AlO, AlSiO, HfO, HfSiO, ZrO, ZrSiO, TiO, TiAlO, BST((Ba,Sr)TiO), STO(SrTiO), BTO(BaTiO), PZT(Pb,Zr,Ti)O), (Pb,La)(Zr,Ti)O, Ba(Zr,Ti)O, Sr(Zr,Ti)O, or a combination thereof.

The upper electrode 230 may include, for example, W, Ru, RuO, Pt, PtO, Ir, IrO, SRO(SrRuO), BSRO((Ba,Sr)RuO), CRO(CaRuO), BaRuO, La(Sr, Co)O, and the like. In some example embodiments, the upper electrode 230 may be made of a metal material. For example, the upper electrode 230 may be made of W.

The semiconductor device 1 includes a substrate 110 on which a plurality of active regions 118 are defined, a plurality of gate dielectric films 122, a plurality of word lines 120, and a plurality of buried insulating films 124 sequentially formed inside a plurality of word line trenches 120T crossing a plurality of active regions 118 in the substrate 110, a mask pattern 112 covering the element isolation film 116, the plurality of active regions 118, and the plurality of buried insulating films 124, a cover insulating film pattern 114 on the mask pattern 112, a plurality of bit line structures 140 on the cover insulating film pattern 114, a plurality of insulating spacer structures 150 covering both sidewalls of the plurality of bit line structures 140, a plurality of buried contacts 170 connected to the plurality of active regions 118 and a plurality of landing pads 190 filling the upper portion and extending to the upper portion of the bit line structure 140 while filling the lower portion of the space defined by the plurality of insulating fences 180 and the plurality of insulating spacer structures 150, and a plurality of capacitor structures 200 including a plurality of lower electrodes 210 connected to the plurality of landing pads 190, a capacitor dielectric layer 220, and an upper electrode 230.

Referring to FIGS. 3A to 17D together, in the semiconductor device 1 according to an example embodiment, a plurality of word line trenches 120T in which a plurality of word lines 120 are disposed are formed by using the plurality of first mask patterns MKG as etch masks, the second mask pattern 112 is used as an etching mask that protects the element isolation film 116 and the plurality of active regions 118 from being removed to form a plurality of conductive semiconductor patterns 132 and a plurality of direct contact conductive patterns 134, and a plurality of mold openings MLO filled with the plurality of lower electrodes 210 are formed using the third mask pattern MKC as an etching mask.

Therefore, in the manufacturing method of the semiconductor device 1 according to an example embodiment, design rules are reduced and the process difficulty of forming components of the semiconductor device 1 having an increased aspect ratio, for example, a plurality of word lines 120, a plurality of direct contact conductive patterns 134, or a plurality of lower electrodes 210, may be improved.

FIGS. 18A and 18B are enlarged cross-sectional views illustrating a mask pattern used in a method of manufacturing a semiconductor device, according to some example embodiments.

Referring to FIG. 18A, the mask pattern MK may have a stacked structure including a lower amorphous retention layer LAL, an upper amorphous retention layer UAL, and a main metal oxide mask layer MMOK disposed between the lower amorphous retention layer LAL and the upper amorphous retention layer UAL. The main metal oxide mask layer MMOK may be referred to as a first mask layer, and each of the lower amorphous retention layer LAL and the upper amorphous retention layer UAL may be referred to as a second mask layer. In some example embodiments, the lower amorphous retention layer LAL and the upper amorphous retention layer UAL may be referred to as a lower mask layer and an upper mask layer, respectively. The mask pattern MK may be at least one of the first mask pattern MKG shown in FIGS. 4A to 4D, the preliminary mask layer 112P shown in FIGS. 7A to 7D and the second mask pattern 112 shown in FIGS. 8A to 8D, and the third mask patterns MKC shown in FIGS. 14A to 14D. In some example embodiments, the mask pattern MK may be the preliminary mask layer 112P shown in FIGS. 7A to 7D and the second mask pattern 112 shown in FIGS. 8A to 8D.

Each of the main metal oxide mask layer MMOK, the lower amorphous retention layer LAL, and the upper amorphous retention layer UAL may be amorphous. For example, the main metal oxide mask layer MMOK may include an amorphous metal oxide. In some example embodiments, each of the lower amorphous retention layer LAL and the upper amorphous retention layer UAL may include an amorphous metal oxide or an amorphous insulating material that does not contain metal.

Each of the lower amorphous retention layer LAL and the upper amorphous retention layer UAL may be made of a material having a higher crystallization temperature than that of the main metal oxide mask layer MMOK. For example, the main metal oxide mask layer MMOK may be made of a material having a crystallization temperature of 900° C. or less, and each of the lower amorphous retention layer LAL and the upper amorphous retention layer UAL may be made of a material that has a crystallization temperature of 1000° C. or higher or does not crystallize and remains amorphous even in an atmosphere of 1000° C. or higher. In some example embodiments, the main metal oxide mask layer MMOK may be made of HfO₂ or ZrO₂, and each of the lower amorphous retention layer LAL and the upper amorphous retention layer UAL may be made of Al₂O₃, SiN, or SiO₂. Because the lower amorphous retention layer LAL and the upper amorphous retention layer UAL cover the lower and upper surfaces of the main metal oxide mask layer MMOK, respectively, the main metal oxide mask layer MMOK may remain amorphous without being crystallized even in an atmosphere of 900° C. or higher.

The main metal oxide mask layer MMOK may have a first thickness T1, the lower amorphous retention layer LAL may have a second thickness T2, and the upper amorphous retention layer UAL may have a third thickness T3. The first thickness T1 may have a greater value than each of the second thickness T2 and the third thickness T3. In some example embodiments, each of the second thickness T2 and the third thickness T3 may be about 10% to about 30% of the first thickness T1. For example, when the first thickness T1 is 20 Å or less, each of the second and third thicknesses T2 and T3 may be about 2 Å to about 6 Å. The total thickness TTK of the mask pattern MK may be the sum of the first thickness T1, the second thickness T2, and the third thickness T3.

Referring to FIG. 18B, the mask pattern MKa may include a main metal oxide mask layer MMOKa disposed between the lower amorphous retention layer LAL, the upper amorphous retention layer UAL, and including a plurality of sub-mask layers SMOK1, SMOK2, SMOK3, and SMOK4 spaced apart from each other in the vertical direction (Z direction), and at least one intermediate amorphous retention layer MAL1, MAL2, and MAL3 disposed between a corresponding pair of adjacent ones of the plurality of sub-mask layers SMOK1, SMOK2, SMOK3, and SMOK4. It is shown in FIG. 18B that the plurality of sub-mask layers SMOK1, SMOK2, SMOK3, and SMOK4 include a first sub-mask layer SMOK1, a second sub-metal oxide mask layer SMOK2, a third sub-mask layer SMOK3, and a fourth sub-mask layer SMOK4, and at least one of the intermediate amorphous retention layers MAL1, MAL2, and MAL3 includes a first intermediate amorphous retention layer MAL1, a second intermediate amorphous retention layer MAL2, and a third intermediate amorphous retention layer MAL3, but the number of sub-mask layers SMOK1, SMOK2, SMOK3, and SMOK4 and the number of at least one of the intermediate amorphous retention layers MAL1, MAL2, and MAL3 may not be limited thereto. The number of sub-mask layers SMOK1, SMOK2, SMOK3, and SMOK4 may be greater than the number of at least one intermediate amorphous retention layer MAL1, MAL2, and MAL3 by one.

All of the plurality of sub-mask layers SMOK1, SMOK2, SMOK3, and SMOK4, or each of the first sub-mask layer SMOK1, the second sub-mask layer SMOK2, the third sub-mask layer SMOK3, and the fourth sub-mask layers SMOK4 may be called a first mask layer, and each of the lower amorphous retention layer LAL, the upper amorphous retention layer UAL, the first intermediate amorphous retention layer MAL1, the second intermediate amorphous retention layer MAL2, and the third intermediate amorphous retention layer MAL3 may be called a second mask layer. In some example embodiments, the lower amorphous retention layer LAL and the upper amorphous retention layer UAL may be referred to as a lower mask layer and an upper mask layer, respectively, and each of the first intermediate amorphous retention layer MAL1, the second intermediate amorphous retention layer MAL2, and the third intermediate amorphous retention layer MAL3 may be referred to as an intermediate mask layer. The mask pattern Mka may be at least one of the first mask pattern MKG shown in FIGS. 4A to 4D, the preliminary mask layer 112P shown in FIGS. 7A to 7D and the second mask pattern 112 shown in FIGS. 8A to 8D, and the third mask patterns MKC shown in FIGS. 14A to 14D. In some example embodiments, the mask pattern MK may be the preliminary mask layer 112P shown in FIGS. 7A to 7D and the second mask pattern 112 shown in FIGS. 8A to 8D.

Each of the main metal oxide mask layer MMOKa, the lower amorphous retention layer LAL, the upper amorphous retention layer UAL, and the at least one intermediate amorphous retention layer MAL1, MAL2, and MAL3 may be amorphous. For example, the main metal oxide mask layer MMOKa may include an amorphous metal oxide. In some example embodiments, each of the lower amorphous retention layer LAL, the upper amorphous retention layer UAL, and at least one of intermediate amorphous retention layer MAL1, MAL2, and MAL3 may include an amorphous metal oxide or an amorphous insulating material that does not include metal.

Each of the lower amorphous retention layer LAL, the upper amorphous retention layer UAL, and at least one of intermediate amorphous retention layer MAL1, MAL2, and MAL3 may be made of a material having a higher crystallization temperature than the main metal oxide mask layer MMOKa. For example, the main metal oxide mask layer MMOKa may be made of a material having a crystallization temperature of 900° C. or less, and each of the lower amorphous retention layer LAL, the upper amorphous retention layer UAL, and at least one of intermediate amorphous retention layers MAL1, MAL2, and MAL3 may be made of a material that has a crystallization temperature of 1000° C. or higher or may maintain an amorphous state without crystallization even in an atmosphere of 1000° C. or higher. In some example embodiments, the main metal oxide mask layer MMOKa may be made of HfO₂ or ZrO₂, and each of the lower amorphous retention layer LAL, the upper amorphous retention layer UAL, and at least one of the intermediate amorphous retention layers MAL1, MAL2, and MAL3 may be formed of Al₂O₃, SiN, or SiO₂. Because each of the lower amorphous retention layer LAL, the upper amorphous retention layer UAL, and at least one of the intermediate amorphous retention layers MAL1, MAL2, and MAL3 covers the lower and upper surfaces of each of the plurality of sub-mask layers SMOK1, SMOK2, SMOK3, and SMOK4, each of the plurality of sub-mask layers SMOK1, SMOK2, SMOK3, and SMOK4 included in the main metal oxide mask layer MMOKa may remain amorphous without being crystallized even in an atmosphere of 900° C. or higher.

The first sub-mask layer SMOK1, the second sub-metal oxide mask layer SMOK2, the third sub-mask layer SMOK3, and the fourth sub-mask layer SMOK4 may have a first thickness T1a, a second thickness T2a, a third thickness T3a, and a fourth thickness T4a, respectively, and the lower amorphous retention layer LAL, the first intermediate amorphous retention layer MAL1, the second intermediate amorphous retention layer MAL2, the third intermediate amorphous retention layer MAL3, and the upper amorphous retention layer UAL, may have a fifth thickness T5a, a sixth thickness T6a, a seventh thickness T7a, an eighth thickness T8a, and a ninth thickness T9a, respectively.

The first thickness T1a, the second thickness T2a, the third thickness T3a, and the fourth thickness T4a may have values greater than the fifth thickness T5a, the sixth thickness Ta, the seventh thickness T7a, the eighth thickness T8a, and the ninth thickness T9a, respectively. In some example embodiments, the fifth thickness T5a, the sixth thickness T6a, the seventh thickness Ta, the eighth thickness T8a, and the ninth thickness T9a may be about 10% to about 30% of the first thickness T1a, the second thickness T2a, the third thickness T3a, and the fourth thickness T4a, respectively. In some example embodiments, the sum of the fifth thickness T5a, the sixth thickness T6a, the seventh thickness T7a, the eighth thickness T8a, and the ninth thickness T9a may be about 10% to about 30% of the sum of the first thickness T1a, the second thickness T2a, the third thickness T3a, and the fourth thickness T4a.

When each of the first thickness T1a, the second thickness T2a, the third thickness T3a, and the fourth thickness T4a is 20 Å or less, each of the fifth thickness T5a, the sixth thickness T6a, the seventh thickness Ta, the eighth thickness T8a, and the ninth thickness T9a may be about 2 Å to about 6 Å. In some example embodiments, the first thickness T1a, the second thickness T2a, the third thickness T3a, and the fourth thickness T4a may have substantially the same value, and each of the fifth thickness T5a, the sixth thickness T6a, the seventh thickness T7a, the eighth thickness T8a, and the ninth thickness T9a may have substantially the same value. The total thickness TTKa of the mask pattern Mka may be the sum of the first thickness T1a, the second thickness T2a, the third thickness T3a, the fourth thickness T4a, the fifth thickness T5a, the sixth thickness T6a, the seventh thickness T7a, the eighth thickness T8a, and the ninth thickness T9a.

FIGS. 19A and 19B are enlarged cross-sectional views illustrating a semiconductor device according to some example embodiments. Specifically, FIGS. 19A and 19B are enlarged cross-sectional views illustrating an enlarged portion XIX of FIG. 17A.

Referring to FIG. 19A, the second mask pattern 112 may have a stacked structure including a lower amorphous retention layer LAL, an upper amorphous retention layer UAL, and a main metal oxide mask layer MMOK disposed between the lower amorphous retention layer LAL and the upper amorphous retention layer UAL. For example, the second mask pattern 112 may be the mask pattern MK shown in FIG. 18A.

A horizontal width of the cover insulating film pattern 114 in the first horizontal direction (X direction) may have a value smaller than that of the second mask pattern 112, and a lower surface of the insulating spacer structure 150 may be positioned at a lower vertical level than an upper surface of the cover insulating film pattern 114. A lower surface of the insulating spacer structure 150 may contact the second mask pattern 112. For example, the lower surface of the insulating spacer structure 150 may contact the upper amorphous retention layer UAL. In some example embodiments, the lower surface of the insulating spacer structure 150 may be positioned at the same vertical level as the upper surface of the second mask pattern 112 or the lower surface of the cover insulating film pattern 114.

Referring to FIG. 19B, the second mask pattern 112 may have a stacked structure including a lower amorphous retention layer LAL, an upper amorphous retention layer UAL, and a main metal oxide mask layer MMOK disposed between the lower amorphous retention layer LAL and the upper amorphous retention layer UAL. For example, the second mask pattern 112 may be the mask pattern MK shown in FIG. 18A.

A horizontal width of the cover insulating film pattern 114 in the first horizontal direction (X direction) may have a value smaller than that of the second mask pattern 112, and a lower surface of the insulating spacer structure 150 may be positioned at a lower vertical level than a lower surface of the cover insulating film pattern 114. A lower surface of the insulating spacer structure 150 may contact the second mask pattern 112. For example, the lower surface of the insulating spacer structure 150 may contact the main metal oxide mask layer MMOK. In some example embodiments, the lower surface of the insulating spacer structure 150 may be positioned at a lower vertical level than the lower surface of the second mask pattern 112. That is, the insulating spacer structure 150 may extend into the second mask pattern 112 from the top of the second mask pattern 112. In some example embodiments, the horizontal width of the cover insulating film pattern 114 in the first horizontal direction (X direction) may have substantially the same value as the horizontal width of the upper amorphous retention layer UAL.

FIGS. 20A and 20B are enlarged cross-sectional views illustrating a mask pattern used in a method of manufacturing a semiconductor device, according to some example embodiments.

Referring to FIG. 20A, the mask pattern MKb may include a hard mask layer HMK, a lower amorphous retention layer LAL covering the hard mask layer HMK, an upper amorphous retention layer UAL on the lower amorphous retention layer LAL, and a main metal oxide mask layer MMOK disposed between the lower amorphous retention layer LAL and the upper amorphous retention layer UAL. The main metal oxide mask layer MMOK, the lower amorphous retention layer LAL, and the upper amorphous retention layer UAL are substantially the same as the main metal oxide mask layer MMOK, the lower amorphous retention layer LAL, and the upper amorphous retention layer UAL shown in FIG. 18A, and thus a detailed explanation thereof is omitted. The mask pattern MKb may be at least one of the first mask pattern MKG shown in FIGS. 4A to 4D and the third mask pattern MKC shown in FIGS. 14A to 14D.

The hard mask layer HMK may be a metal mask layer including metal. In some example embodiments, the hard mask layer HMK may be a metal doped mask layer. For example, the hard mask layer HMK may be a mask layer including at least one of Si, C, B, and N and doped with metal.

Referring to FIG. 20B, the mask pattern MKc may include a hard mask layer HMK, a lower amorphous retention layer LAL covering the hard mask layer HMK, an upper amorphous retention layer UAL on the lower amorphous retention layer LAL, a main metal oxide mask layer MMOKa including a plurality of sub-mask layers SMOK1, SMOK2, SMOK3, and SMOK4 disposed between the lower amorphous retention layer LAL and the upper amorphous retention layer UAL and spaced apart from each other in the vertical direction (Z direction), and at least one of intermediate amorphous retention layer MAL1, MAL2, and MAL3 disposed between each of the plurality of sub-mask layers SMOK1, SMOK2, SMOK3, and SMOK4. The main metal oxide mask layer MMOKa, the lower amorphous retention layer LAL, the upper amorphous retention layer UAL, and at least one of the intermediate amorphous retention layers MAL1, MAL2, and MAL3 are substantially the same as the main metal oxide mask layer MMOKa, the lower amorphous retention layer LAL, the upper amorphous retention layer UAL, and at least one of the intermediate amorphous retention layers MAL1, MAL2, and MAL3 shown in FIG. 18B, and then a detailed description thereof is omitted. The mask pattern MKc may be at least one of the first mask pattern MKG shown in FIGS. 4A to 4D and the third mask pattern MKC shown in FIGS. 14A to 14D. The hard mask layer HMK may be a metal mask layer including metal. In some example embodiments, the hard mask layer HMK may be a metal doped mask layer.

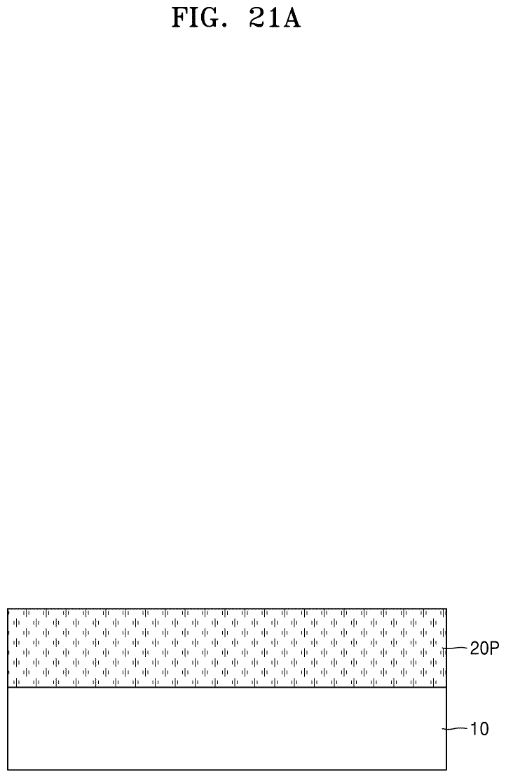

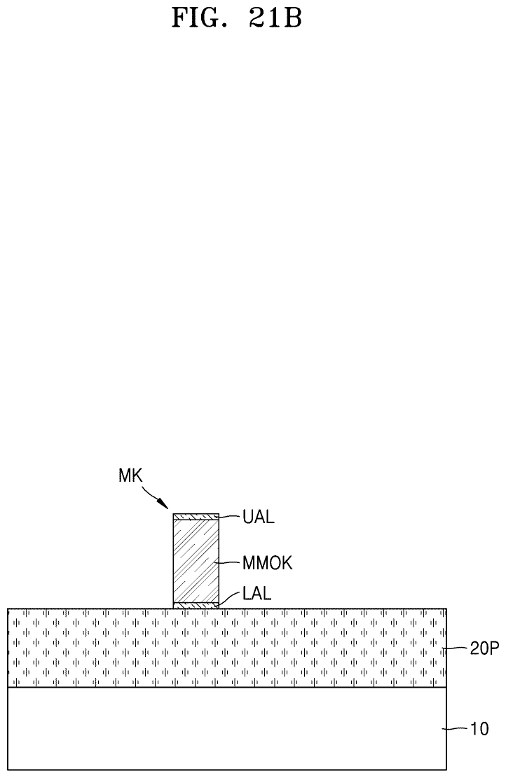

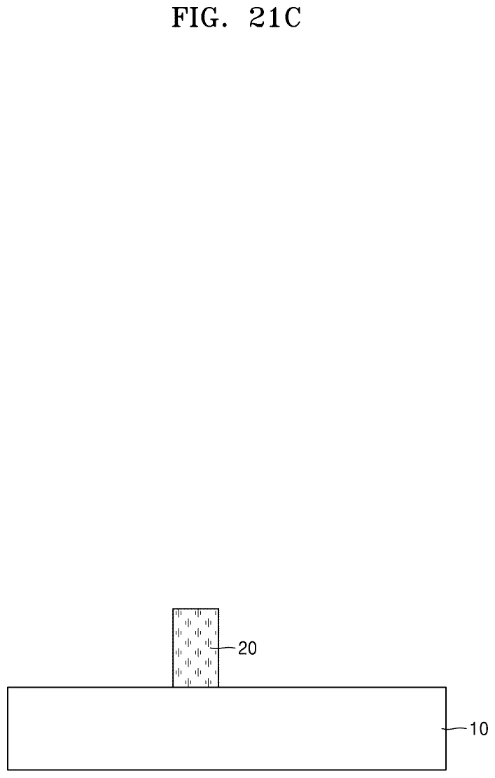

FIGS. 21A to 21C are cross-sectional views illustrating a method of manufacturing a semiconductor device, using a mask pattern according to an example embodiment.

Referring to FIG. 21A, a target layer 20P is formed on the substrate 10. The target layer 20P may include the element isolation film 116 and the plurality of active regions 118 shown in FIGS. 3A to 3D, and the mold layer MLD shown in FIGS. 14A to 14D.

Referring to FIG. 21B, a mask pattern MK is formed on the target layer 20P. FIG. 21B shows the mask pattern MK shown in FIG. 18A, but the inventive concepts are not limited thereto, and instead of forming the mask pattern MK, a mask pattern MKb further including a hard mask layer HMK shown in FIG. 20A may be formed.

Referring to FIGS. 21B and 21C, the resulting pattern 20 may be formed by etching the target layer 20P using the mask pattern MK as an etch mask. The resulting pattern 20 may include an element isolation film 116 and a plurality of active regions 118 defining a plurality of word line trenches 120T shown in FIGS. 5A to 5D, or a mold layer MLD defining a plurality of mold openings MLO shown in FIGS. 15A to 15D.

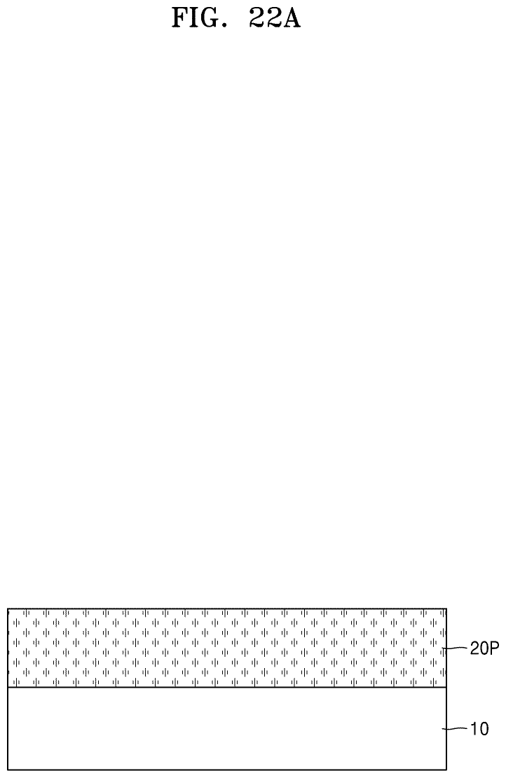

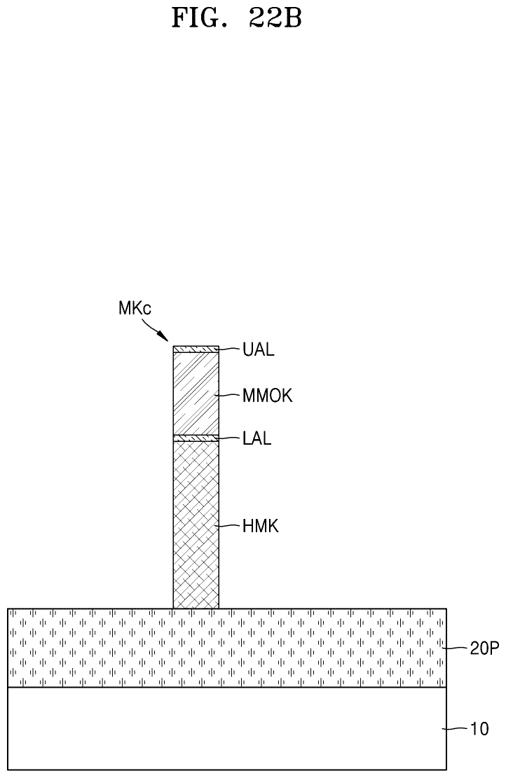

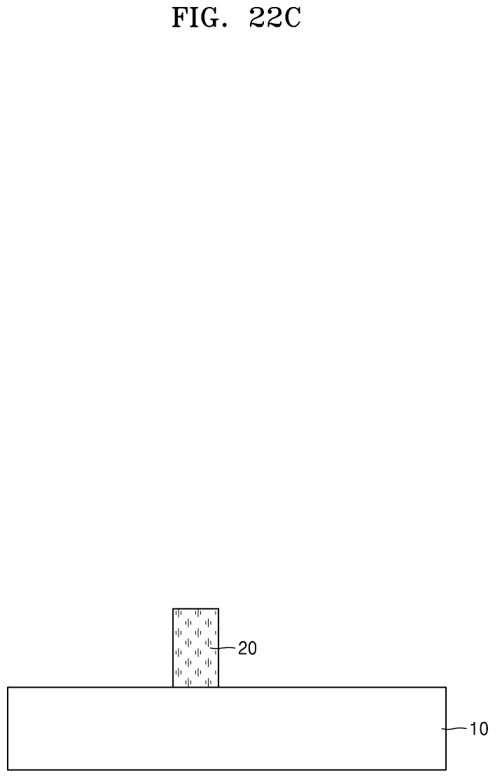

FIGS. 22A to 22C are cross-sectional views illustrating a method of manufacturing a semiconductor device, using a mask pattern according to an example embodiment.

Referring to FIG. 22A, a target layer 20P is formed on the substrate 10. The target layer 20P may include the element isolation film 116 and the plurality of active regions 118 shown in FIGS. 3A to 3D, and the mold layer MLD shown in FIGS. 14A to 14D.

Referring to FIG. 22B, a mask pattern MKc including a mask pattern Mka shown in FIG. 18B may be formed on the target layer 20P. Specifically, FIG. 22B shows that a mask pattern MKc may further include a hard mask layer HMK between the mask pattern Mka and the target layer 20P.

Referring to FIGS. 22B and 22C together, the resulting pattern 20 may be formed by etching the target layer 20P using the mask pattern Mka and the a hard mask layer HMK as an etch mask. The resulting pattern 20 may include an element isolation film 116 and a plurality of active regions 118 defining a plurality of word line trenches 120T shown in FIGS. 5A to 5D, or a mold layer MLD defining a plurality of mold openings MLO shown in FIGS. 15A to 15D.

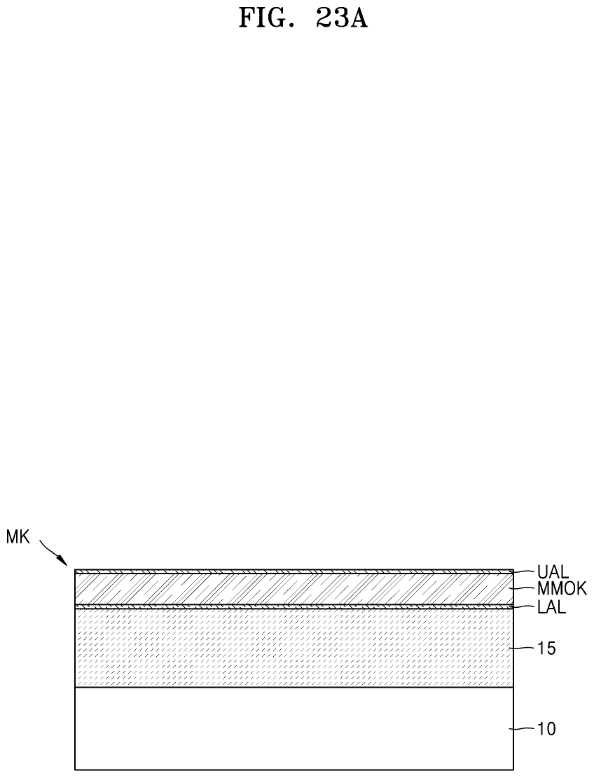

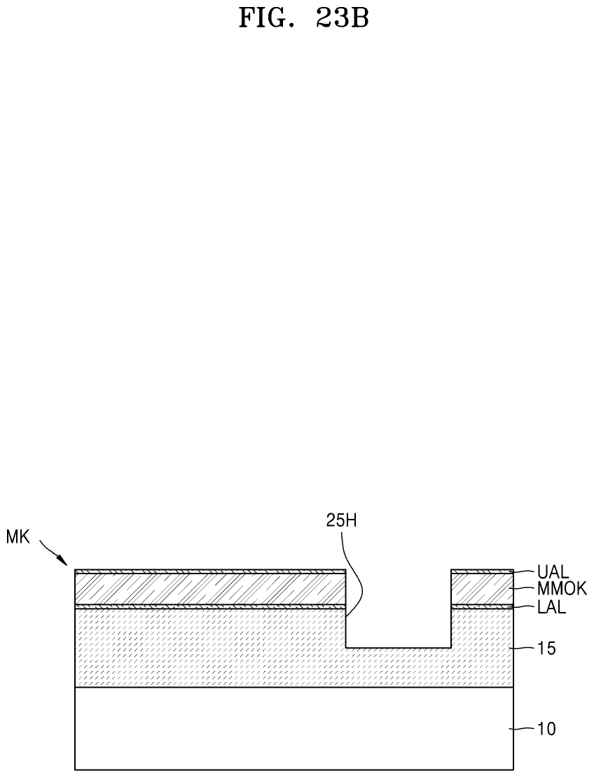

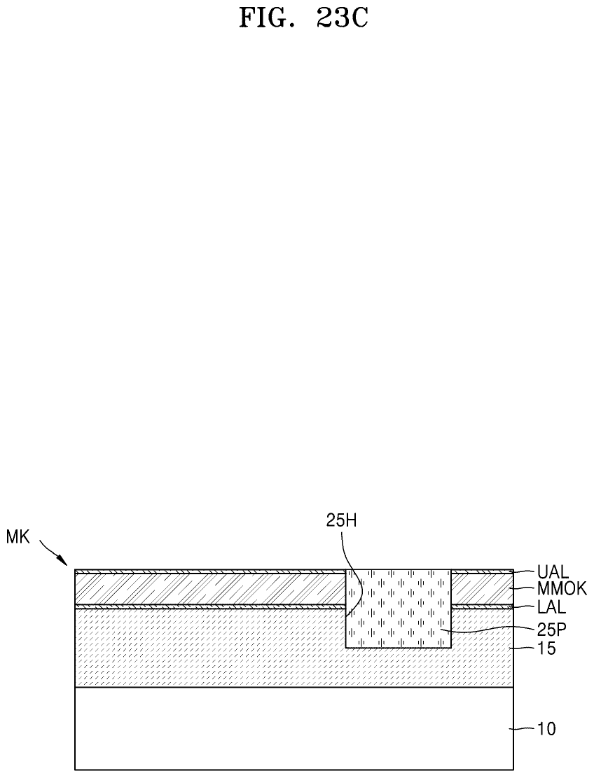

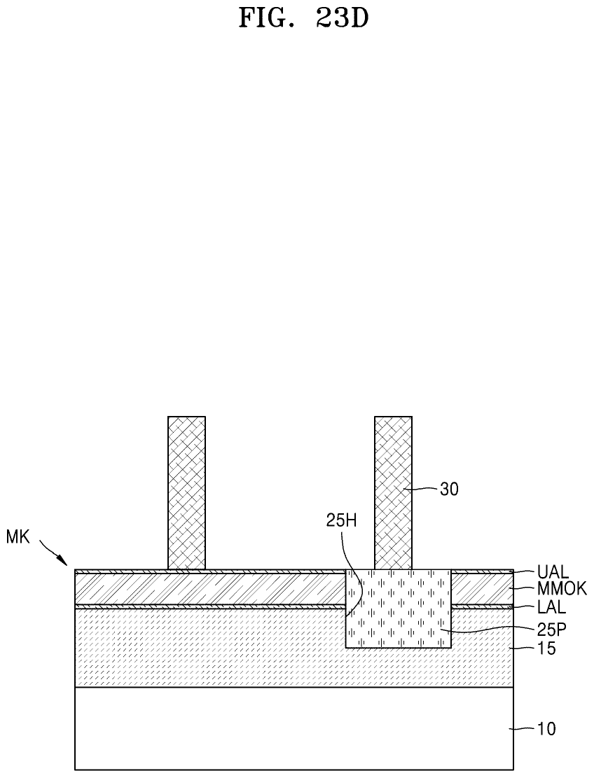

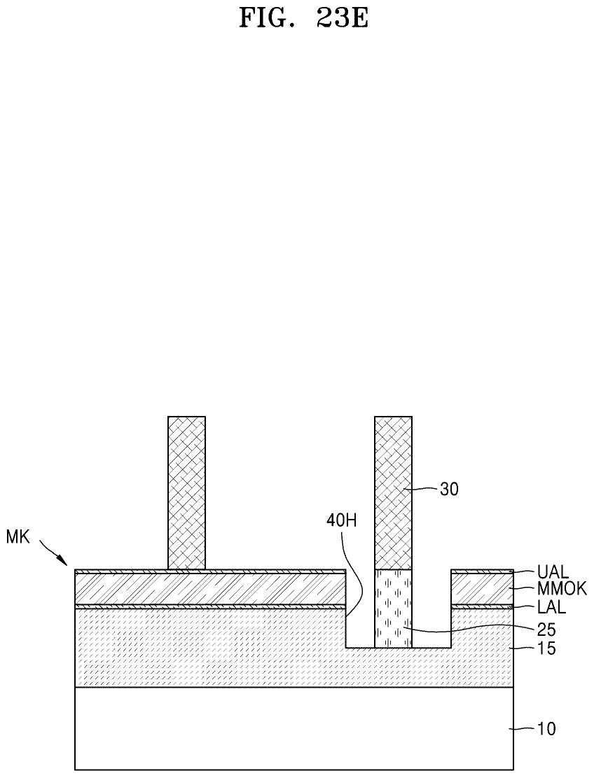

FIGS. 23A to 23E are cross-sectional views illustrating a method of manufacturing a semiconductor device, using a mask pattern according to an example embodiment.

Referring to FIG. 23A, after forming the base layer 15 covering the substrate 10, a mask pattern MK is formed on the base layer 15. The base layer 15 may include the element isolation film 116 and the plurality of active regions 118 shown in FIGS. 3A to 3D. FIG. 23A shows the mask pattern MK shown in FIG. 18A, but the inventive concepts are not limited thereto, and instead of forming the mask pattern MK, the mask pattern Mka shown in FIG. 18B may be formed.

Referring to FIG. 23B, a first contact hole 25H exposing the base layer 15 is formed through the mask pattern MK. The first contact hole 25H may be formed to extend into the base layer 15. The first contact hole 25H may be the direct contact hole 134H shown in FIGS. 8A to 8D.

Referring to FIG. 23C, a target layer 25P filling the first contact hole 25H is formed. The target layer 25P may be the direct contact conductive layer 134P shown in FIGS. 9A to 9D. The target layer 25P may be made of metal or a metal compound that is a conductive material (e.g., conductive metal compound).

Referring to FIG. 23D, a plurality of mask pattern structures 30 are formed on the mask pattern MK and the target layer 25P. The plurality of mask pattern structures 30 may be the plurality of bit line structures 140 shown in FIGS. 10A to 10D. The plurality of mask pattern structures 30 may be formed to cover a portion of the mask pattern MK and a portion of the target layer 25P.

Referring to FIG. 23D, the resulting pattern 25 and the second contact hole 40H are formed by etching the target layer 25P using the plurality of mask pattern structures 30 and the mask pattern MK as an etch mask. A portion of the target layer 25P covered by the plurality of mask pattern structures 30 may become the resulting pattern 25. A portion of the base layer 15 covered by the mask pattern MK may be protected without being removed in the process of forming the resulting pattern 25. The resulting pattern 25 may be the direct contact conductive pattern 134 shown in FIGS. 10A to 10D, and the second contact hole 40H may be the buried contact hole 170H shown in FIGS. 10A to 10D.

While the inventive concepts have been particularly shown and described with reference to some example embodiments thereof, it will be understood that various changes in form and details may be made therein without departing from the spirit and scope of the following claims.

What is claimed is:

1. A manufacturing method of a semiconductor device, the method comprising:
preparing a substrate including a plurality of active regions defined by an element isolation film;
forming a word line trench extending in a first horizontal direction across the plurality of active regions in the substrate by removing a portion of the element isolation film and a portion of each of the plurality of active regions using a first mask pattern;
forming a word line within the word line trench;
forming a second mask pattern defining a direct contact hole extending into the substrate on the substrate where the word line is formed;
forming a direct contact conductive layer including metal or a metal compound as a conductive material to fill the direct contact hole;
forming a plurality of bit line structures, each including a bit line, the plurality of bit line structures being parallel to each other in the first horizontal direction and extending in a second horizontal direction orthogonal to the first horizontal direction on the second mask pattern and the direct contact conductive layer;
forming a plurality of direct contact conductive patterns by etching the direct contact conductive layer using the plurality of bit line structures and the second mask pattern as etching masks;
forming a plurality of buried contacts and a plurality of landing pads on the plurality of buried contacts, the plurality of buried contacts electrically connected to the plurality of active regions, and the plurality of landing pads filling a portion of a space between the plurality of bit line structures;
forming a mold layer on the plurality of bit line structures and the plurality of landing pads;
forming a plurality of mold openings by etching the mold layer using a third mask pattern; and
forming a plurality of lower electrodes filling the plurality of mold openings,
wherein at least one of the first mask pattern, the second mask pattern, and the third mask pattern has a stacked structure of a first mask layer and at least two second mask layers, the first mask layer including an amorphous metal oxide, and the at least two second mask layers including an amorphous metal oxide or an amorphous insulating material that does not include metal.

2. The method of claim 1, wherein the at least two second mask layers comprise an upper mask layer covering an upper surface of the first mask layer and a lower mask layer covering a lower surface of the first mask layer.

3. The method of claim 2, wherein a thickness of each of the upper mask layer and the lower mask layer is about 10% to about 30% of a thickness of the first mask layer.

4. The method of claim 2, wherein
the first mask layer comprises a plurality of sub-mask layers spaced apart from each other in a vertical direction, and
the at least two second mask layers further comprise an intermediate mask layer disposed between each of the plurality of sub-mask layers.

5. The method of claim 4, wherein
a thickness of each of the plurality of sub-mask layers is 20 Å or less, and
a thickness of each of the at least two second mask layers is greater than 2 Å, and is about 10% to about 30% of a thickness of each of the plurality of sub-mask layers.

6. The method of claim 1, wherein the at least two second mask layers include a material having a crystallization temperature that is higher than a crystallization temperature of the first mask layer.

7. The method of claim 1, wherein the first mask layer includes HfO₂ or ZrO₂, and each of the at least two second mask layers include Al₂O₃.

8. The method of claim 1, wherein at least one of the first mask pattern and the third mask pattern further comprises a hard mask layer disposed under the first mask layer and the at least two second mask layers.

9. The method of claim 8, wherein the hard mask layer is a metal mask layer doped with metal.

10. The method of claim 1, further comprising:
forming a cover insulating film pattern to be between the second mask pattern and a corresponding one of the plurality of bit line structures in a vertical direction,
wherein a horizontal width of the cover insulating film pattern is less than a horizontal width of the second mask pattern.

11. The method of claim 10, further comprising:
forming a conductive semiconductor pattern to be between the corresponding one of the plurality of bit line structures and the cover insulating film pattern in a vertical direction,
wherein a horizontal width of the cover insulating film pattern and a horizontal width of the conductive semiconductor pattern are equal to each other.

12. The method of claim 11, further comprising:
forming an insulating spacer structure covering each of both sidewalls of each of the plurality of bit line structures,
wherein a lower surface of the insulating spacer structure is at a vertical level lower than an upper surface of the cover insulating film pattern and in contact with the second mask pattern.

13. A manufacturing method of a semiconductor device, the method comprising:
forming a target layer on a substrate;
forming a mask pattern on the substrate including the target layer; and
forming a resulting pattern by etching the target layer using the mask pattern,
wherein the mask pattern comprises,
a first mask layer containing an amorphous metal oxide; and
an upper mask layer and a lower mask layer including an amorphous metal oxide or an amorphous insulating material that does not include metal, the an upper mask layer and the lower mask layer covering upper and lower surfaces of the first mask layer, respectively.

14. The method of claim 13, wherein the mask pattern further comprises a hard mask layer disposed under the lower mask layer and including metal.

15. The method of claim 13, wherein the target layer is made of metal or a conductive metal compound.

16. The method of claim 15, further comprising:
forming a mask pattern structure on the target layer,
wherein the resulting pattern is a portion of the target layer overlapping the mask pattern structure.

17. A manufacturing method of a semiconductor device, the method comprising:
forming a base layer covering a substrate;
forming a mask pattern on the base layer;
patterning the base layer to define a first contact hole therein using the mask pattern;
forming a target layer including metal or a conductive metal compound while filling the first contact hole;
forming a mask pattern structure on the mask pattern and the target layer; and
forming a resulting pattern and a second contact hole by etching the target layer using the mask pattern and the mask pattern structure as an etch mask,
wherein the mask pattern comprises,
a first mask layer containing an amorphous metal oxide; and
an upper mask layer and a lower mask layer including an amorphous metal oxide or an amorphous insulating material that does not include metal, the upper mask layer and the lower mask layer covering upper and lower surfaces of the first mask layer, respectively.

18. The method of claim 17, wherein
the first mask layer comprises a plurality of sub-mask layers spaced apart from each other in a vertical direction, and
the method further comprises an intermediate mask layer disposed between each of the plurality of sub-mask layers and including an amorphous insulating material including an amorphous metal oxide or not including metal.

19. The method of claim 18, wherein a thickness of each of the upper mask layer, the lower mask layer, and the intermediate mask layer is about 10% to about 30% of a thickness of each of the plurality of sub-mask layers.

20. The method of claim 18, wherein each of the plurality of sub-mask layers has a thickness of 20 Å or less.
